(19) United States
(12) Patent Application Publication
(10) Pub. No.: US 2026/0313791 A1
(43) Pub. Date: Oct. 8, 2026

(54) CIRCUIT BOARD AND SEMICONDUCTOR PACKAGE COMPRISING SAME

(71) Applicant: LG INNOTEK CO., LTD., Seoul (KR)

(72) Inventors: Tae Hyun KIM, Seoul (KR); Byung Kwan JUNG, Seoul (KR); Il Sik NAM, Seoul (KR)

(21) Appl. No.: 19/483,829

(22) PCT Filed: May 13, 2024
(86) PCT No.: PCT/KR2024/006509

§ 371 Date: Nov. 12, 2025

(30) Foreign Application Priority Data
May 12, 2023 (KR) 10-2023-0061897
May 16, 2023 (KR) 10-2023-0062994

(51) Int. Cl. H05K 1/11; H05K 1/181; H05K 3/40

(52) U.S. Cl. CPC H05K 1/111; H05K 1/181; H05K 3/4007; H05K 2201/09381; H05K 2201/094; H05K 2201/099; H05K 2201/10522

(57) ABSTRACT

A circuit board according to an embodiment includes an insulating layer; and a lower pad part disposed on a lower surface of the insulating layer, wherein the lower pad part includes a plurality of second lower pads disposed along an edge of the lower surface of the insulating layer, a plurality of first lower pads disposed inside the plurality of second lower pads, and a plurality of bump parts disposed on lower surfaces of the plurality of second lower pads.

### CROSS-REFERENCE TO RELATED APPLICATIONS

This application is the U.S. national stage application of International Patent Application No. PCT/KR2024/006509, filed May 13, 2024, which claims the benefit under 35 U.S.C. § 119 of Korean Application Nos. 10-2023-0061897, filed May 12, 2023; and 10-2023-0062994, filed May 16, 2023; the disclosures of each of which are incorporated herein by reference in their entirety.

### TECHNICAL FIELD

An embodiment relates to a circuit board and a semiconductor package including the same.

### BACKGROUND ART

As the performance of electric/electronic products progresses, technologies for attaching a larger number of packages to a limited-sized substrate are being proposed and studied. However, since a general package is based on mounting a single semiconductor device, there is a limit to obtaining a desired performance.

A general package substrate has a form in which a processor package in which a processor chip is disposed and a memory package to which a memory chip is attached are connected into one. Such a package substrate manufactures the processor chip and the memory chip as one integrated package, thereby reducing a mounting area of a chip and enabling high-speed signals through a short pass.

Meanwhile, due to the high specification of electronic devices such as mobile devices and the adoption of High Bandwidth Memory (HBM), a size of the package is increasing, and a package substrate including an interposer are mainly used.

That is, a semiconductor package includes a circuit board and semiconductor devices mounted on upper and lower portions of the circuit board, respectively. For example, the semiconductor package may have a double-side molding structure in which semiconductor devices are mounted on upper and lower portions of the circuit board, respectively, and thus molding is performed at upper and lower portions of the circuit board.

At this time, the circuit board may be greatly warped in a specific direction depending on a thickness of each layer of the insulating layer, a wiring density of an electrode part provided in each layer, a thickness of an electrode part provided in each layer, a thickness of a protective layer, and differences in coefficients of thermal expansion of the insulating layer, the electrode part, and the protective layer. Therefore, in a conventional technology, as the circuit board is greatly warped in a specific direction, there is a problem that the semiconductor device cannot be stably disposed on the circuit board, or injection characteristics of a molding member molding the semiconductor device deteriorates.

### DISCLOSURE

### Technical Problem

The embodiment provides a circuit board having a novel structure and a semiconductor package including the same.

In addition, the embodiment provides a circuit board capable of inhibiting significant warping in a specific direction and a semiconductor package including the same.

In addition, the embodiment provides a circuit board capable of resolving an electrical short circuit problem between adjacent electrodes caused by diffusion of a connection part and a semiconductor package including the same.

In addition, the embodiment provides a circuit board capable of improving injection characteristics of a molding member for molding a semiconductor device and a semiconductor package including the same.

In addition, the embodiment provides a circuit board having a pad capable of improving bonding strength with a connection part and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises an insulating layer; and a lower pad part disposed on a lower surface of the insulating layer, wherein the lower pad part includes: a plurality of second lower pads disposed along an edge of the lower surface of the insulating layer, a plurality of first lower pads disposed inside the plurality of second lower pads, and a plurality of bump parts disposed on lower surfaces of the plurality of second lower pads.

In addition, the circuit board further comprises a lower protective layer disposed under the lower surface of the insulating layer; an upper protective layer disposed on an upper surface of the insulating layer; and an upper pad part disposed between the upper surface of the insulating layer and the upper protective layer.

In addition, a thickness of the lower protective layer in a vertical direction is different from a thickness of the upper protective layer in the vertical direction.

In addition, the thickness of the lower protective layer in the vertical direction is smaller than the thickness of the upper protective layer in the vertical direction, and wherein each of the plurality of first lower pads includes: a first conductive part having a first width and disposed under the lower surface of the insulating layer; and a second conductive part having a second width different from the first width and disposed under a lower surface of the first conductive part.

In addition, a side surface of each of the plurality of first lower pads has a step, and wherein a side surface of at least one of the plurality of second lower pads and the upper pad part does not have a step.

In addition, a side surface of each of the plurality of second lower pads and a side surface of the plurality of upper pad part do not have steps, and wherein a thickness of each of the plurality of first lower pads in the vertical direction is greater than a thickness of at least one of the plurality of second lower pads and the upper pad part in the vertical direction.

In addition, the thickness of each of the plurality of second lower pads and the upper pad part in the vertical direction is the same as a thickness of the first conductive part of the first lower pad in the vertical direction.

In addition, a wiring density of the lower pad part on the lower surface of the insulating layer is smaller than a wiring density of the upper pad part on the upper surface of the insulating layer.

In addition, a first width of the first conductive part is greater than a second width of the second conductive part.

In addition, at least a portion of the bump part overlaps the first conductive part of the first lower pad in a horizontal direction.

In addition, the lower protective layer includes a through hole that overlaps the plurality of first lower pads in a vertical direction as a whole.

Meanwhile, the semiconductor package of the embodiment further comprises a circuit board, a first connection part positioned under the first lower pad of the circuit board, and a first semiconductor device disposed under the first connection part, wherein the through hole overlaps the first semiconductor device in the vertical direction.

In addition, a planar area of the through hole is larger than a planar area of the first semiconductor device.

In addition, an outer surface of the first semiconductor device overlaps the through hole in the vertical direction, and an inner wall of the through hole is formed with a spacing of a specific horizontal distance along a circumferential direction of the outer surface of the first semiconductor device.

In addition, a thickness of the bump part in the vertical direction is greater than a thickness of the second conductive part of the first lower pad in the vertical direction, and a lower surface of the bump part is positioned lower than a lower surface of the lower protective layer and a lower surface of the first lower pad.

In addition, the semiconductor package further comprises a first molding member molding the first semiconductor device and the bump part.

In addition, a width of the upper pad part in the horizontal direction is smaller than a width of each of the first lower pad and the second lower pad in the horizontal direction.

In addition, the semiconductor package further comprises a second connection part disposed on the upper pad part; a second semiconductor device disposed on the second connection part; and a second molding member molding the second semiconductor device.

Meanwhile, according to another embodiment, a semiconductor package comprises a circuit board; a first semiconductor device disposed under the circuit board; a second semiconductor device disposed on the circuit board; and a main board disposed under the first semiconductor device, wherein the circuit board includes: an insulating layer; a plurality of first lower pads disposed under a lower surface of the insulating layer and overlapping the first semiconductor device in the vertical direction; a lower pad part including a plurality of second lower pads disposed to surround the plurality of first lower pads and provided in an outer edge region of a lower surface of the insulating layer; and a bump part disposed under the plurality of second lower pads of the lower pad part and overlapping the first semiconductor device in the horizontal direction, wherein the bump part has a predetermined thickness and is disposed under the circuit board and surrounds an outer surface of the first semiconductor device.

In addition, the circuit board further includes a lower protective layer disposed under a lower surface of the insulating layer; an upper protective layer disposed on an upper surface of the insulating layer; and an upper pad part disposed between an upper surface of the insulating layer and the upper protective layer, wherein a thickness of the lower protective layer in a vertical direction is smaller than a thickness of the upper protective layer in a vertical direction, a thickness of the first lower pad in a vertical direction is larger than a thickness of each of the second lower pad and the upper pad in a vertical direction, and a width of the upper pad in a horizontal direction is smaller than a width of each of the first lower pad and the second lower pad in a horizontal direction.

A circuit board according to an embodiment comprises an insulating layer; and a lower electrode part disposed on a lower surface of the insulating layer, wherein a lower surface of the insulating layer includes an outer region provided along an outer edge of the lower surface of the insulating layer, and an inner region provided inside the outer region, and the lower electrode part includes a plurality of first lower pads provided in the inner region of the lower surface of the insulating layer, a plurality of second lower pads provided in the outer region of the lower surface of the insulating layer; a lower metal part disposed on lower surfaces of the plurality of first lower pads; and a bump part disposed on lower surfaces of the plurality of second lower pads and surrounding a periphery of the inner region, wherein a lower surface of the bump part is positioned lower than a lower surface of the lower metal part, and a width of the lower metal part is different from a width of the first lower pad.

In addition, the first lower pad includes a first conductive part disposed on a lower surface of the insulating layer and having a first width, and a second conductive part disposed on a lower surface of the first conductive part and having a second width different from the first width, and the lower metal part is disposed on a lower surface of the second conductive part of the first lower pad and has a third width different from the second width.

In addition, a metal material constituting the lower metal part is different from metal materials constituting the first conductive part and the second conductive part of the first lower pad.

In addition, the lower metal part includes tin.

In addition, the second width is smaller than the first width, and the third width is smaller than the first width and the second width.

In addition, a side surface of the first conductive part, a side surface of the second conductive part, and a side surface of the lower metal part have a step.

In addition, the second width is smaller than the first width, and the third width is smaller than the first width and larger than the second width.

In addition, the lower metal part includes a first portion provided on the lower surface of the second conductive part and in contact with the lower surface of the second conductive part; and a second portion extending from the first portion toward the lower surface of the insulating layer and in contact with the side surface of the second conductive part.

In addition, the lower metal part includes a first portion provided on the lower surface of the second conductive part and overlapping the second conductive part in the vertical direction; and a second portion extending from the first portion and not overlapping the second conductive part in the vertical direction.

In addition, the second portion of the lower metal part is spaced apart from and does not contact the first conductive part and the second conductive part of the second lower pad.

In addition, the second conductive part of the second lower pad has an inclination whose width decreases from a lower surface toward an upper surface.

In addition, the second portion of the lower metal part includes a bend portion warped toward the lower surface of the insulating layer, and the bend portion overlaps a side surface of the second conductive part having the inclination in the horizontal direction.

In addition, the semiconductor package further comprises a connection part disposed on the lower surface of the lower metal part; and a semiconductor device disposed on the lower surface of the connection part.

In addition, the semiconductor package further comprises a lower protective layer disposed on the lower surface of the insulating layer and having a through hole overlapping the semiconductor device in the vertical direction, wherein a planar area of the through hole is larger than a planar area of the semiconductor device.

In addition, an outer surface of the semiconductor device overlaps the through hole in the vertical direction, and an inner wall of the through hole of the lower protective layer is provided with a spacing of a specific horizontal distance along a circumferential direction of the outer surface of the semiconductor device.

In addition, the semiconductor package further comprises a molding member for molding the bump part and the semiconductor device.

In addition, the semiconductor package further comprises an upper protective layer disposed on an upper surface of the insulating layer; and an upper pad part disposed between an upper surface of the insulating layer and the upper protective layer, wherein a thickness of the lower protective layer in a vertical direction is smaller than a thickness of the upper protective layer in a vertical direction, a thickness of the first lower pad in a vertical direction is larger than a thickness of each of the second lower pad and the upper pad part in a vertical direction, and a width of the upper pad part in a horizontal direction is smaller than a width of each of the first lower pad and the second lower pad in a horizontal direction.

Meanwhile, a semiconductor package according to an embodiment includes a circuit board; a semiconductor device disposed under the circuit board; and a main board disposed under the semiconductor device, wherein the circuit board includes an insulating layer; a lower pad part including a plurality of first lower pads provided in an inner region of a lower surface of the insulating layer that overlaps the semiconductor device in a vertical direction, and a plurality of second lower pads provided to surround a periphery of the plurality of first lower pads and provided in an outer edge region of the lower surface of the insulating layer; a lower metal part disposed on a lower surface of the first lower pad; and a bump part disposed to surround a periphery of the inner region and disposed on a lower surface of the second lower pad, wherein the bump part overlaps the semiconductor device in a horizontal direction, a side surface of the first lower pad has a step, and a width of the lower metal part is different from a width of a lower surface of the first lower pad.

In addition, the first lower pad includes a first conductive part disposed on a lower surface of the insulating layer and having a first width, and a second conductive part disposed on a lower surface of the first conductive part and having a second width different from the first width, and the lower metal part is disposed on a lower surface of the second conductive part of the first lower pad and has a third width different from the second width.

In addition, the circuit board further includes an upper protective layer disposed on an upper surface of the insulating layer; and an upper pad part disposed between the upper surface of the insulating layer and the upper protective layer, wherein a wiring density of the lower pad part on a lower surface of the insulating layer is smaller than a wiring density of the upper pad part on an upper surface of the insulating layer, a thickness of the lower protective layer in a vertical direction is smaller than a thickness of the upper protective layer in a vertical direction, a thickness of the first lower pad in a vertical direction is larger than a thickness of each of the second lower pad and the upper pad part in a vertical direction, and a width of the upper pad part in a horizontal direction is smaller than a width of each of the first lower pad and the second lower pad in a horizontal direction.

### Advantageous Effects

The embodiment can inhibit a circuit board and a semiconductor package from being significantly warped in a specific direction. Furthermore, the embodiment can improve mold injection characteristics of a molding member for molding a semiconductor device, thereby improving product yield.

For example, the circuit board includes a first protective layer provided on a lower surface of an insulating layer and a second protective layer provided on an upper surface of the insulating layer. A thickness of the first protective layer may differ from a thickness of the second protective layer. For example, the circuit board may expand and/or contract due to heat and/or pressure applied in manufacturing and/or usage environments, thereby causing significant warping in a specific direction. In this case, the embodiment can inhibit the circuit board from being significantly warped in a specific direction by applying different thicknesses of the first and second protective layers. For example, if the circuit board is warped in a convex shape, a thickness of the first protective layer is formed to be smaller than that of the second protective layer. For example, if the circuit board is warped in a concave shape, the thickness of the second protective layer is formed to be smaller than that of the first protective layer. Therefore, the embodiment can induce warping in a direction opposite to a warpage direction of the circuit board by utilizing a difference in thickness between the first and second protective layers. Accordingly, the embodiment may inhibit the circuit board from being significantly warped in a specific direction. Accordingly, the embodiment allows the embodiment to more stably mount semiconductor devices on the circuit board, further enhancing operational reliability of semiconductor packages and products including servers.

Furthermore, the circuit board includes a first wiring layer formed on a lower surface of an insulating layer and a second wiring layer formed on an upper surface of the insulating layer. At this time, one of the first and second wiring layers includes a first pad part includes a side surface with a step. At this time, the wiring layer including the first pad part is disposed closer to a protective layer having a relatively smaller thickness among the first and second protective layers. For example, the thickness of the first protective layer may be smaller than that of the second protective layer, and the first pad part may be provided on the first wiring layer. For example, the thickness of the second protective layer may be smaller than that of the first protective layer, and the first pad part may be provided on the second wiring layer.

That is, it may be difficult to completely inhibit warpage of the circuit board simply by adjusting the thicknesses of the first and second protective layers. Accordingly, the embodiment allows a through hole to be provided in the first protective layer having a relatively small thickness, and allows a first pad part having a step to be provided in the through hole of the first protective layer.

For example, the first pad part includes a first conductive part and a second conductive part having different widths in the horizontal direction. Accordingly, the embodiment allows the side surface of the first pad part to have a step, thereby increasing a contact area with a connection part, such as solder. For example, the embodiment can increase the contact area between the first pad part and the connection part by a thickness of the second conductive part in the vertical direction, compared to a comparative example structure without a step, thereby improving the bonding strength with the connection part. Accordingly, the embodiment may allow the semiconductor device to be stably mounted, and further, may allow the semiconductor device to operate stably.

Furthermore, the embodiment may allow a connection part to be disposed under the second conductive part of the first pad part having a relatively small width, thereby reducing a volume of the connection part and inhibiting electrical shorts due to diffusion and/or expansion of the connection part.

Furthermore, the embodiment can more easily control a flowability of the connection part by providing a step on the side surface of the first pad part, thereby resolving electrical shorts that may occur due to horizontal expansion and/or diffusion of the connection part. For example, a cross-sectional area of the first pad part can be increased by providing a step on the side surface of the first pad part. In addition, as the cross-sectional area of the first pad part increases, a distance between adjacent connection parts can be increased, thereby resolving an electrical short circuit problem in which adjacent connection parts are electrically connected to each other according to the diffusion and/or expansion of the connection parts.

Furthermore, a thickness of the first pad part in the vertical direction may be smaller than a thickness of the first protective layer in the vertical direction. For example, a sum of the thickness of the first conductive part and the thickness of the second conductive part of the first pad part may be smaller than the thickness of the first protective layer. For example, a lower surface of the second conductive part of the first pad part may be positioned higher than a lower surface of the first protective layer. Therefore, the embodiment can facilitate the injection of the first molding member into the through hole of the first protective layer, thereby improving mold injection characteristics and product yield.

The embodiment allows a second pad part to surround the first pad part, and allows a bump part to be provided on the lower surface of the second pad part. For example, the first pad part may be provided in an inner region of the lower surface of the insulating layer, and the second pad part may be provided in an outer region of the lower surface of the insulating layer surrounding the first pad part. In addition, a width of the second pad part may be greater than a width of the first pad part, and a bump part having a greater thickness than the second conductive part of the first pad part may be provided on the lower surface of the second pad part. Through this, the embodiment can further improve a rigidity of the outer region of the circuit board, and thus can more efficiently inhibit the circuit board from being significantly warped in a specific direction. Furthermore, since the first pad part includes the first conductive part and the second conductive part, the embodiment can reduce the process difficulty in a process of mounting a semiconductor device on the first pad part, thereby improving the product yield. Furthermore, the embodiment can provide the second pad part and the bump part to surround the first pad part, thereby securing the rigidity of the circuit board, and thus inhibiting the circuit board from being significantly warped in a specific direction.

In addition, the embodiment allows the thickness of the first protective layer to be smaller than that of the second protective layer, thereby solving the problem that the mold injection characteristics of the molding member deteriorate as the circuit board is warped in a convex shape.

In addition, the embodiment allows the through hole of the first protective layer to have a larger area than the semiconductor device, and allows an inner wall of the through hole of the first protective layer to be spaced apart by a spacing of a horizontal distance along the circumferential direction of an outer surface of the semiconductor device. According, the embodiment inhibits the first protective layer from overlapping the outer surface of the semiconductor device in the vertical direction, thereby securing an additional vertical distance between the semiconductor device and the circuit board to correspond to the thickness of the first protective layer, thereby further improving the mold injection characteristics of the molding member. Accordingly, the embodiment may inhibit voids from being provided in the molding member, and further allow the semiconductor device to be stably protected by the molding member. Therefore, the embodiment may allow the semiconductor device to operate more stably and allow products such as the semiconductor package and a server including the same to operate more stably.

In addition, the embodiment may further include a lower metal part on the second conductive part of the first pad part. The lower metal part may have a different width from the second conductive part of the first pad part. For example, the width of the second conductive part of the first pad part may be different from the width of the lower metal part. In this case, the lower metal part may include a metal material different from metal materials of the first conductive part and the second conductive part of the first pad part. For example, the lower metal part may include tin with excellent bonding strength. Accordingly, the embodiment may additionally include a lower metal part on the first pad part, further improving the bonding strength between the first pad part and the connection part, and enabling a semiconductor device to be more stably mounted on the first pad part.

In addition, the embodiment may further improve the contact area between the connection part, the first pad part, and the lower metal part by providing a step between the lower metal part and the first pad part, thereby further improving the bonding strength. In addition, the embodiment can more easily control the flowability of the connection part by having a step between the lower metal part and the first pad part, thereby more efficiently inhibiting electrical short-circuiting due to expansion and/or diffusion of the connection part.

In another embodiment, the lower metal part may have a width greater than the width of the second conductive part of the first pad part. In this case, the lower metal part includes a first portion that overlaps the first pad part in the vertical direction and contacts the first pad part. In addition, the lower metal part may include a second portion that extends outward from the first portion and does not overlap the second conductive part of the first pad part in the vertical direction and does not contact the second conductive part. Accordingly, the embodiment allows the lower metal part to include a second portion that does not overlap the second conductive part in the vertical direction and does not contact the second conductive part, thereby further enhancing the bonding strength between the first pad part and the connection part. For example, the second portion of the lower metal part can function as an anchor when coupled with the connection part, thereby allowing the connection part to be more firmly coupled onto the first pad part. Accordingly, the embodiment can further enhance the bonding strength between the connection part and the first pad part, and further enable the semiconductor device to be mounted more stably on the circuit board.

### DESCRIPTION OF DRAWINGS

FIG. 1 is a view illustrating a circuit board according to a first embodiment.

FIG. 2 is a view illustrating a semiconductor package including the circuit board of FIG. 1.

FIG. 3(a) and 3(b) are views illustrating an electrical reliability problem that occurs when a circuit board is warped in a specific direction.

FIG. 4 is a plan view illustrating a first wiring layer provided on a lower surface of an insulating layer of FIG. 1.

FIG. 5 is an enlarged cross-sectional view of a region A of FIG. 1.

FIG. 6 is a plan view illustrating a through hole of a first protective layer vertically overlapping the first wiring layer of FIG. 3(a) and 3(b).

FIG. 7(a) and 7(b) are views illustrating a mold injection characteristic problem that occurs when the circuit board is warped in a specific direction.

FIG. 8 is a plan view illustrating a positional relationship between a through hole provided in the first protective layer and a semiconductor device.

FIG. 9(a) and 9(b) are views for explaining a difference in mold injection characteristics according to a difference in structure of through holes of an embodiment and a comparative example.

FIG. 10 is a cross-sectional view illustrating a circuit board according to a second embodiment.

FIG. 11 is a cross-sectional view illustrating a circuit board according to a third embodiment.

FIG. 12 is a cross-sectional view illustrating a circuit board according to a fourth embodiment.

FIG. 13 is a plan view illustrating a first wiring layer provided on the lower surface of the insulating layer of FIG. 12.

FIGS. 14 to 18 are enlarged cross-sectional views illustrating a region A of FIG. 12 according to various embodiments.

FIG. 19 is a cross-sectional view illustrating a structure in which a main board is coupled to the semiconductor package of FIG. 2.

FIGS. 20 to 28 are cross-sectional views illustrating a manufacturing method of the circuit board illustrated in FIG. 1 in order of processes.

### BEST MODE

Hereinafter, embodiments will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and redisposed.

In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art. Further, the terms used in the embodiments of the present invention are for describing the embodiments and are not intended to limit the present invention.

In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “connected” to another element, it may include not only when the element is directly “connected” to, “coupled” to, or “connected” to other elements, but also when the element is “connected”, “coupled”, or “connected” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only an upper direction but also a lower direction based on one element.

### Electronic Device

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor chip in the form of an integrated circuit (IC) in which hundreds to millions of devices are integrated in one semiconductor device. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

In addition, the semiconductor device may be an integrated passive device (IPD). In addition, the semiconductor device may be a multilayer ceramic capacitor (MLCC) or a silicon-based capacitor.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

### Circuit Board and Semiconductor Package

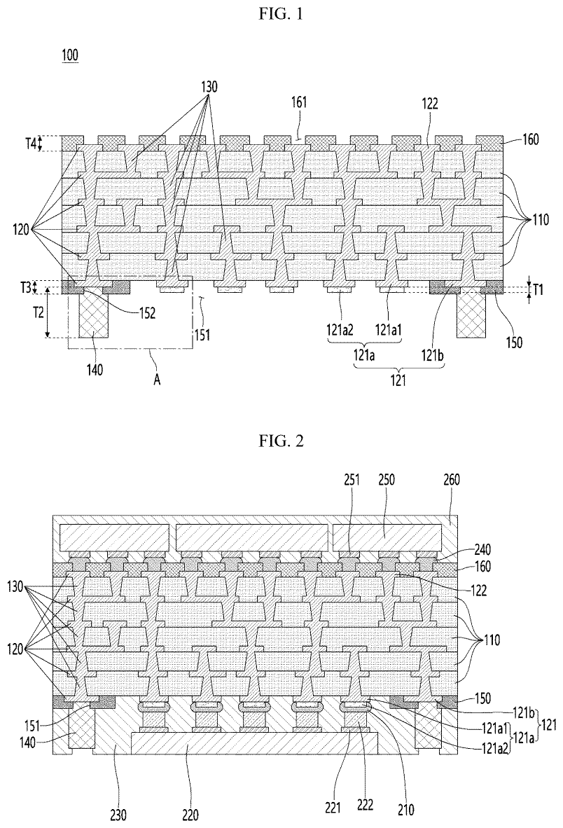

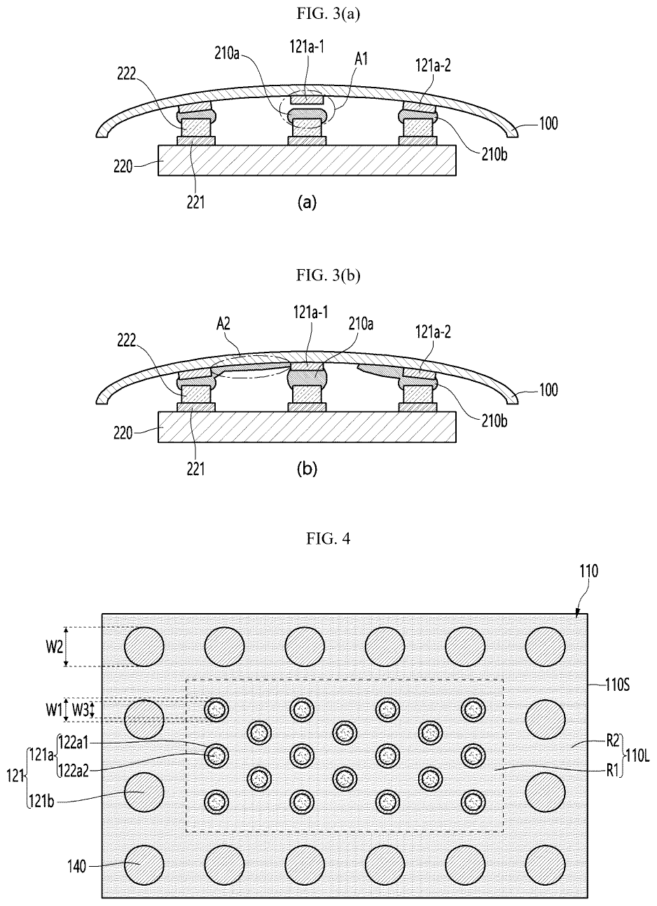

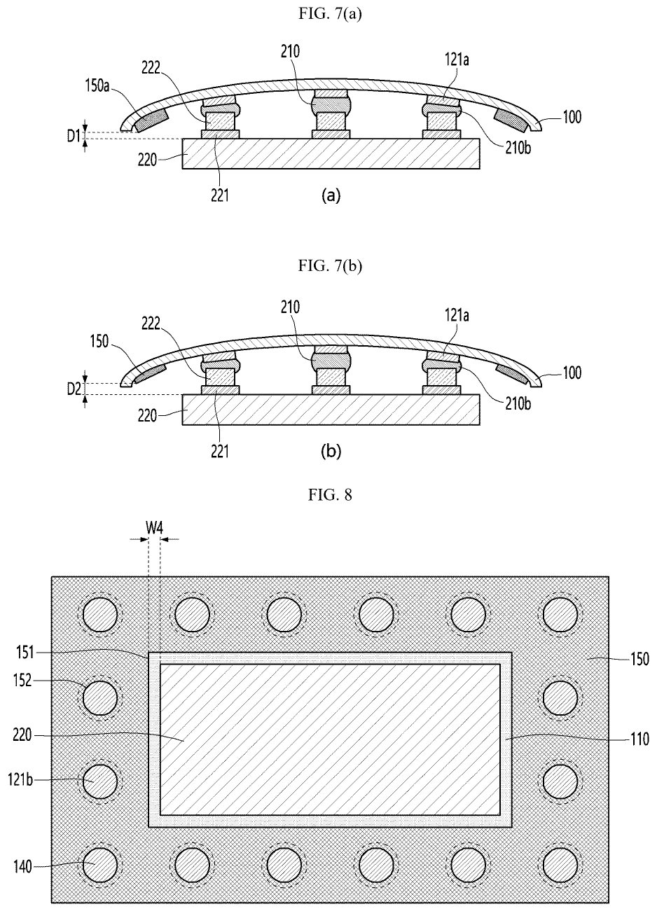

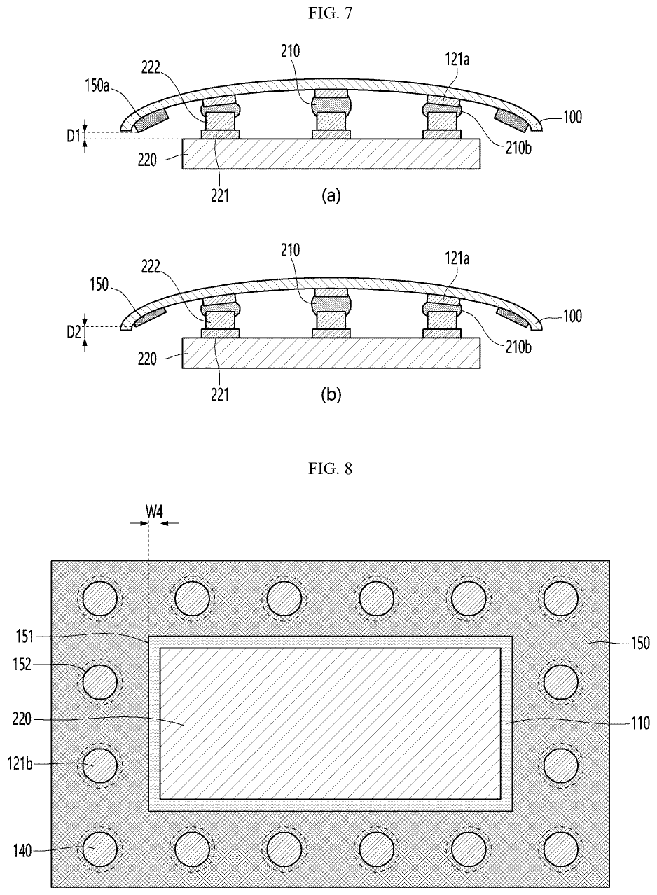

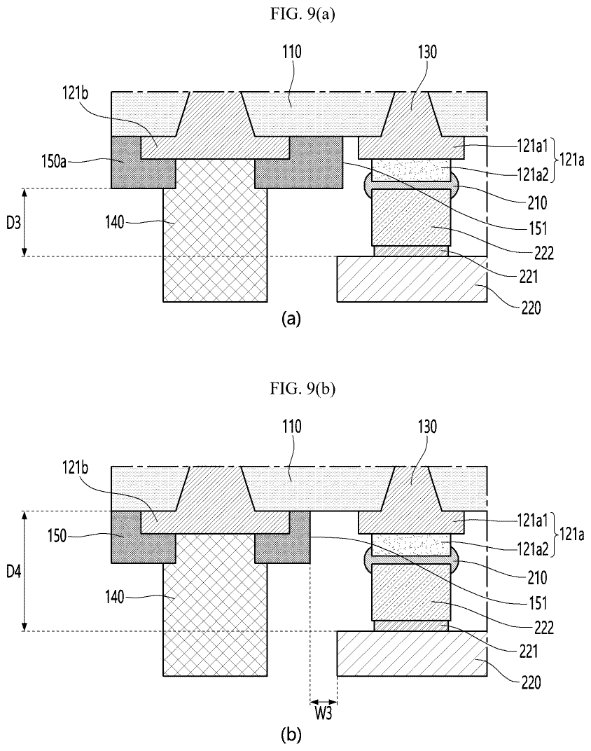

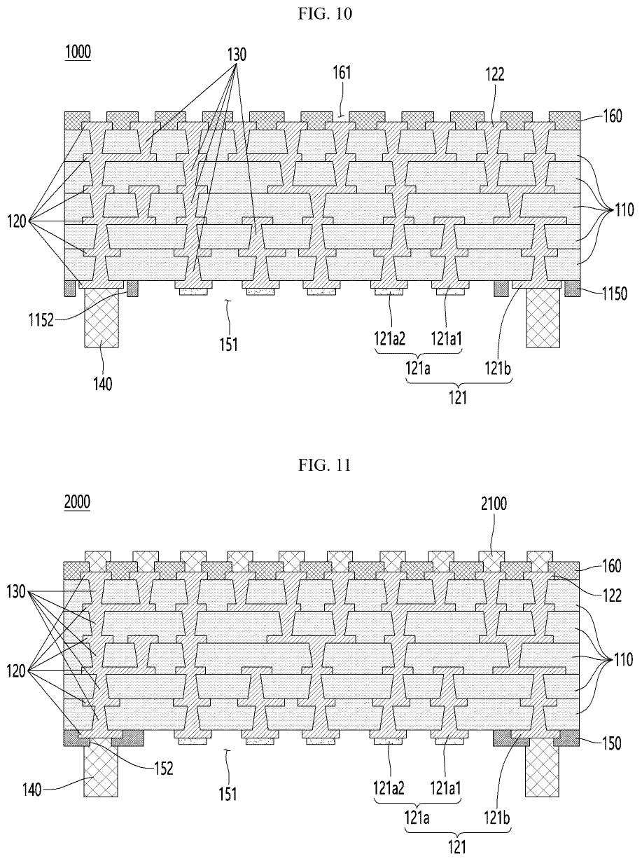

FIG. 1 is a view illustrating a circuit board according to a first embodiment, FIG. 2 is a view illustrating a semiconductor package including the circuit board of FIG. 1, FIG. 3(a) and 3(b) are views illustrating an electrical reliability problem that occurs when a circuit board is warped in a specific direction, FIG. 4 is a plan view illustrating a first wiring layer provided on a lower surface of an insulating layer of FIG. 1, FIG. 5 is an enlarged cross-sectional view of a region A of FIG. 1, FIG. 6 is a plan view illustrating a through hole of a first protective layer vertically overlapping the first wiring layer of FIG. 3(a) and 3(b), FIG. 7(a) and 7(b) are views illustrating a mold injection characteristic problem that occurs when the circuit board is warped in a specific direction, FIG. 8 is a plan view illustrating a positional relationship between a through hole provided in the first protective layer and a semiconductor device, and FIG. 9(a) and 9(b) are diagrams for explaining a difference in mold injection characteristics according to a difference in structure of through holes of an embodiment and a comparative example.

Before describing the embodiment, the semiconductor package of the embodiment may have a double-side molding structure in which semiconductor devices 220 and 250 are mounted on both sides of a circuit board 100, and molding members 230 and 260 are provided to mold the semiconductor devices 220 and 250 mounted on both sides of the circuit board 100.

At this time, the circuit board 100 may be significantly warped in a specific direction due to heat and/or pressure applied during a manufacturing process and/or in an operating environment in which the semiconductor devices 220 and 250 operate. In one example, the circuit board 100 may be warped in a convex shape with both ends facing downward. In another example, the circuit board 100 may be warped in a concave shape with both ends facing upward.

Accordingly, the embodiment changes structures of the protective layer 150 and 160, the wiring layer 121 and 122, and/or the bump part 140 provided on upper and/or lower side of the circuit board 100 in consideration of a direction in which the circuit board 100 is warped, thereby inhibiting the circuit board 100 from being warped significantly in a specific direction, thereby allowing the semiconductor device 220 and 250 to be stably mounted or the semiconductor device 220 and 250 to be stably operated. Furthermore, the embodiment adjusts a thickness of the protective layer 150 and 160 provided on the upper and/or lower side of the circuit board 100 and/or widths of through hole 151, 152, and 161 of the protective layer 150 and 160, thereby improving injection characteristics of the molding member 230 and 260 that molds the semiconductor device 220 and 250.

In this case, hereinafter, a structure of the semiconductor package when the circuit board 100 is warped in a convex shape toward an upper direction will be described. However, the embodiment is not limited thereto, and the circuit board 100 may be warped in a concave shape toward a downward direction. In this case, the first protective layer 150, the first wiring layer 121, and the bump part 140 described below may be provided on an upper surface of the insulating layer 110, and the second protective layer 160 and the second wiring layer 122 may be provided on a lower surface of the insulating layer 110.

Referring to FIGS. 1 and 2, the semiconductor package includes a circuit board 100, connection parts 210 and 240, semiconductor devices 220 and 250, and molding members 230 and 260.

Hereinafter, the circuit board 100 of the embodiment will be preferentially described.

The circuit board 100 includes an insulating layer 110.

The insulating layer 110 may include an organic material that does not include a reinforcing member, enabling excellent processability, slimming of the board, and miniaturization of electrode parts (e.g., wiring electrodes 120) provided in the circuit board 100. For example, the insulating layer 110 of the circuit board can use ABF (Ajinomoto Build-up Film), a product released by Ajinomoto, and FR-4, BT (Bismaleimide Triazine), PID (Photo Image-able Dielectric Resin), BT, etc., but is not limited thereto.

The insulating layer 110 may be formed by stacking a plurality of layers. As illustrated in FIG. 1, the insulating layer 110 may have a five-layer stack structure, but is not limited thereto. For example, the insulating layer 110 may have four or fewer layers, or six or more layers.

In one embodiment, the plurality of layers of the insulating layer 110 may be formed of a same insulating material. However, the embodiment is not limited thereto, and at least one of the plurality of layers of the insulating layer 110 may include an insulating material different from at least the other layers.

Through the laminated structure of the insulating layer 110 described above, the circuit board of the embodiment can electrically connect the semiconductor device and the main board.

At least one of the plurality of layers of the insulating layer 110 of one embodiment includes a reinforcing member. In one embodiment, the reinforcing member may refer to glass fiber. In another embodiment, the reinforcing member may refer to GCP (Glass Core Primer). If the reinforcing member refers to glass fiber and a thickness of the insulating layer including the reinforcing member exceeds 80 μm, the insulating layer including the reinforcing member exceeding 80 μm may be provided as a core layer, and thus, the circuit board may be provided as a core board.

Furthermore, the rigidity of the circuit board 100 can be improved by including a reinforcing member in at least one of the plurality of layers of the insulating layer 110. For example, the reinforcing member can function to inhibit the circuit board and semiconductor package from being significantly warped in a specific direction. Therefore, the insulating layer 110 can be inhibited from being warped during the manufacturing process of the circuit board 100, thereby improving the positional accuracy of the wiring electrode 120 and via electrode 130 of the electrode part, and further improving the alignment between the wiring electrode 120 and via electrode 130. In addition, as the rigidity of the circuit board is secured, the semiconductor device may be stably coupled to the circuit board, thereby allowing the semiconductor device to operate stably. Furthermore, it is possible to stably operate an electronic product such as a server to which a semiconductor package of the embodiment is applied, and thus product reliability may be improved.

The circuit board 100 includes an electrode part. The electrode part includes a wiring electrode 120, a via electrode 130, and a bump part 140.

The wiring electrode 120 may be horizontally disposed between each of the plurality of layers of the insulating layer 110, and the via electrode 130 may be vertically disposed to pass through each of the plurality of layers of the insulating layer 110.

The wiring electrode 120 may include pads and/or traces. The pads of the wiring electrode 120 may overlap the via electrode 130 in a vertical direction, and thus may refer to electrodes directly connected to the via electrode 130. The traces of the wiring electrode 120 may refer to thin, long signal lines connected to the pads of the wiring electrode 120 and thus transmitting signals between a plurality of pads.

The wiring electrode 120 includes a wiring layer disposed on an outermost layer of the insulating layer 110. The wiring layer may refer to wiring electrodes provided on uppermost and lowermost layers among wiring electrodes 120 provided on each layer of the insulating layer 110.

The wiring electrode 120 includes a first wiring layer 121 and a second wiring layer 122.

The first wiring layer 121 may refer to a wiring electrode provided on the lowermost layer among the wiring electrodes provided in each layer of the insulating layer 110, and the second wiring layer 122 may refer to a wiring electrode provided on the uppermost layer among the wiring electrodes provided in each layer of the insulating layer 110. However, the embodiment is not limited thereto, and positions of the first wiring layer 121 and the second wiring layer 122 may be interchanged. For example, in another embodiment, the first wiring layer 121 described below may refer to a wiring electrode provided on the uppermost layer among the wiring electrodes provided in each layer of the insulating layer 110, and the second wiring layer 122 may refer to a wiring electrode provided on the lowermost layer among the wiring electrodes provided in each layer of the insulating layer 110.

The first wiring layer 121 may include a pad part comprising a plurality of pads spaced apart from each other in the horizontal direction on a lower surface of the insulating layer 110. Here, if the insulating layer 110 is comprised of multiple layers, a lower surface of the insulating layer 110 may refer to a lower surface of an insulating layer provided at a lowest position among the multiple layers.

The first wiring layer 121 includes a first pad part 121a and a second pad part 121b. The first wiring layer 121 may be referred to as a lower wiring layer, and the first pad part 121a and the second pad part 121b may be referred to as a lower pad part. For example, the lower pad part may include a plurality of lower pads including the first pad part 121a and the second pad part 121b. For example, the first pad part 121a may be referred to as a plurality of first lower pads of the lower pad part, and the second pad part 121b may be referred to as a plurality of second lower pads of the lower pad part.

The first pad part 121a and the second pad part 121b may be provided in different regions of the lower surface of the insulating layer 110 and spaced apart from each other in the horizontal direction.

The first pad part 121a may be provided in an inner region R1 of the lower surface 110L of the insulating layer 110. Furthermore, the second pad part 121b may be provided in an outer region R2 of the lower surface 110L of the insulating layer 110.

For example, the second pad part 121b may be provided in the outer region R2 of the lower surface 110L of the insulating layer 110. For example, the second pad part 121b may be provided in the outer region R2 of the lower surface of the insulating layer 110 adjacent to a side surface 110S of the insulating layer 110.

A plurality of second pad parts 121b may be provided in the outer region R2 of the lower surface 110L of the insulating layer 110. For example, a plurality of second pad parts 121b may be provided along a circumferential direction or an outer edge direction of the lower surface 110L of the insulating layer 110 in the outer region R2 of the lower surface 110L of the insulating layer 110.

The first pad part 121a may be provided in the inner region R1 of the lower surface 110L of the insulating layer 110. For example, the first pad part 121a may be provided further apart from the side surface 110S of the insulating layer 110 than the second pad part 121b.

The first pad part 121a may be surrounded by the second pad part 121b. For example, the first pad part 121a may be provided inside the outer region R2 surrounded by the second pad part 121b, and the second pad part 121b may be provided outside the inner region R1 of the lower surface 110L of the insulating layer 110 on which the first pad part 121a is disposed.

Referring to FIG. 4, the second pad part 121b may have a second width W2, and the first pad part 121a may have a first width W1 different from the second width W2. The second width W2 of the second pad part 121b may be greater than the first width W1 of the first pad part 121a. For example, the second width W2 of the second pad part 121b may correspond to a width of a terminal provided in a main board of an electronic device coupled to a circuit board. For example, the first width W1 of the first pad part 121a may correspond to a width of a terminal provided in a semiconductor device coupled to the circuit board.

In an embodiment, a second pad part 121b having a width greater than that of the first pad part 121a may surround the first pad part 121a and be provided in an outer region R2 of the lower surface 110L of the insulating layer 110. Through this, the embodiment can increase the rigidity of the outer region R2 of the circuit board using the second pad part 121b and inhibit the circuit board from being significantly warped in a specific direction.

For example, the second pad part 121b can inhibit the circuit board from being warped in a convex shape and/or a concave shape. For example, the embodiment can ensure rigidity in the outer region R2 of the lower surface 110L of the insulating layer 110 by making the second pad part 121b have a width greater than the width of the first pad part 121a. Through this, the embodiment can inhibit the circuit board from being significantly warped in a specific direction and can allow that a semiconductor device to stably mounted on the circuit board. For example, an embodiment may inhibit both ends of the circuit board 100 from being warped in an upward direction and/or a downward direction by using the second pad part 121b having a relatively large width.

For example, the circuit board may be warped in a convex or concave shape depending on a thickness of each layer of the insulating layer 110, physical properties of each layer of the insulating layer 110, a wiring density of the wiring electrode 120 provided in each layer of the insulating layer 110, etc. In addition, if the circuit board is warped in a specific direction, heights of the lower surfaces of the first pad part 121a of the first wiring layer 121 provided in the circuit board may vary, and thus, the semiconductor device may not be stably mounted on the lower surface of the first pad part 121a of the first wiring layer 121.

For example, referring to FIG. 3(a) and 3(b), the circuit board 100 may be warped in a convex shape toward an upward direction.

At this time, if the circuit board 100 is warped in a specific direction, the first pad part 121a of the first wiring layer 121 provided in the circuit board 100 may have different heights depending on positions.

For example, the first pad part 121a may include a first-first pad 121a-1 and a first-second pad 121a-2. The first-first pad 121a-1 may refer to a pad that is positioned further from the outer surface of the circuit board 100 (or located further inward) than the first-second pad 121a-2 among the plurality of first pads of the first pad part 121a. The first-second pad 121a-2 may refer to a pad that is positioned closer (or further outward) to the outer surface of the circuit board 100 than the first-first pad 121a-1 among the plurality of first pads of the first pad part 121a.

At this time, if the circuit board 100 is warped in a convex shape, the lower surface of the first-first pad 121a-1 and the lower surface of the first-second pad 121a-2 may have different heights. For example, a lower surface of the first-second pad 121a-2, which is positioned relatively close to the side surface of the circuit board 100, may be positioned lower than the lower surface of the first-first pad 121a-1.

Accordingly, if the circuit board 100 is greatly warped in a specific direction, the first pad part 121a provided in the circuit board 100 may have different heights depending on the positions, and thus it may be difficult to control a volume of a connection part 210a and 210b such as solder provided between the terminal 221 of the semiconductor device 220 and/or a conductive pillar 222 and the first pad part 121a, and thus an electrical short-circuit problem and/or an electrical open problem may occur.

For example, referring to FIG. 3(a), when a volume of the connection part 210a and 210b is adjusted based on the position of the lower surface of the first-second pad 121a-2 of the first pad part 121a, a volume of the connection part 210a may be insufficient between the first-first pad 121a-1 of the first pad part 121a located relatively high and the terminal 221 and/or conductive pillar 222 of the semiconductor device 220, and accordingly, an electrical reliability problem may occur in which the first-first pad 121a-1 of the first pad part 121a and the terminal 221 and/or conductive pillar 222 of the semiconductor device 220 are electrically opened A1.

For example, referring to FIG. 3(b), if the volume of the connection part 210a and 210b is adjusted based on the position of the lower surface of the first-first pad 121a-1 of the first pad part 121a, the volume of the connection part 210b between the first-second pad 121a-2 of the first pad part 121a that is positioned relatively low and the terminal 221 and/or conductive pillar 222 of the semiconductor device 220 may become too large, and thus the connection part 210b may expand in the horizontal direction. In addition, if the connection part 210b expands, an electrical reliability problem, such as an electrical short A2 in which the connection part 210b connected to the first-second pad 121a-2 is electrically connected to a neighboring first-first pad 121a-1, may occur.

Accordingly, the embodiment allows the first pad part 121a to be disposed in the inner region R1 of the lower surface 110L of the insulating layer 110 and allows the second pad part 121b to be disposed in the outer region R2 of the lower surface 110L of the insulating layer 110 surrounding the first pad part 121a along the circumferential direction or outer edge direction of the lower surface 110L of the insulating layer 110. Accordingly, the embodiment can inhibit the circuit board from being significantly warped in a specific direction by using the second pad part 121b having a relatively large width, thereby enabling the semiconductor device to be stably disposed on the circuit board. Therefore, the embodiment can enable the semiconductor device to operate stably, and thereby enable the semiconductor package and products such as servers to which the semiconductor package is applied to operate stably.

The second wiring layer 122 can be provided on the upper surface of the insulating layer 110. Here, when the insulating layer 110 is provided in a plurality of layers, the upper surface of the insulating layer 110 may refer to an upper surface of an uppermost insulating layer among the plurality of layers of the insulating layer. The second wiring layer 122 may have a different arrangement structure from the first wiring layer 121. For example, the second wiring layer 122 may only have third pad parts corresponding to the first pad part 121a provided in the first wiring layer 121, but is not limited thereto. The second wiring layer 122 may be referred to as an upper pad part.

In one example, the second wiring layer 122 may include a third pad part having a third width smaller than the first width W1 of the first pad part 121a and the second width W2 of the second pad part 121b provided in the first wiring layer 121.

At this time, a relatively larger number of semiconductor devices and/or semiconductor devices having a relatively small width and/or pitch may be disposed on an upper portion of the circuit board 100 of the semiconductor package of the embodiment than in a lower portion of the circuit board 100. In this case, a manufacturing process of the semiconductor package may preferentially perform a process of mounting the semiconductor device in an upper region of the circuit board, which has a relatively large number of semiconductor devices and/or semiconductor devices having a relatively small width and/or pitch, among an upper region and a lower region of the circuit board. Here, the circuit board 100 may be warped larger in a specific direction due to expansion and/or contraction of the insulating layer 110, the first protective layer 150, and/or the second protective layer 160 according to heat and/or pressure applied in the mounting process of the semiconductor device in the upper region. In this case, the process of mounting the semiconductor device in the lower region of the circuit board may not proceed smoothly, and the difficulty of the manufacturing process may increase, resulting in a decrease in product yield, or electrical reliability problems such as electrical short circuits and/or electrical opening.

Therefore, the first wiring layer 121 provided on the lower surface of the insulating layer 110 includes a second pad part 121b provided in the outer region R2 and a first pad part 121a provided in the inner region R1, thereby inhibiting the circuit board from being significantly warped in a specific direction while ensuring a smooth semiconductor device mounting process. Therefore, the embodiment can reduce the difficulty of the semiconductor device mounting process, thereby improving product yield, and furthermore, can resolve electrical shorts and/or electrical opens between the first wiring layer 121 and the terminals of the semiconductor device.

A via electrode 130 may be formed by filling through holes formed in a plurality of layers of the insulating layer 110 with a conductive material. The via electrode 130 is connected to the wiring electrode 120. The via electrode 130 may vertically connect wiring electrodes formed in different layers.

At this time, a side surface of the first pad part 121a may have a step. For example, the first pad part 121a may be formed in a plurality of layers having different widths.

For example, the first pad part 121a may include a first conductive part 121a1 formed on the lower surface of the insulating layer 110. The first conductive part 121a1 of the first pad part 121a may be formed on the lower surface of the insulating layer 110 with a first width W1. A first metal layer 121a1 of the first pad part 121a may overlap with the second pad part 121b in the horizontal direction. The first conductive part 121a1 of the first pad part 121a may have a same thickness in the vertical direction as the second pad part 121b. For example, the first conductive part 121a1 of the first pad part 121a may be a part formed simultaneously with the second pad part 121b in a same process.

For example, the first pad part 121a may have a two-layer structure, and to this end, two plating processes may be performed. At this time, the second pad part 121b may be formed together with the first conductive part 121a1 of the first pad part 121a during a plating process for forming the first conductive part 121a1, and thus, the first conductive part 121a1 of the first pad part 121a may have a same thickness as the second pad part 121b.

The first pad part 121a may include a second conductive part 121a2 disposed under the first conductive part 121a1. The second conductive part 121a2 may be a portion formed by performing an additional plating process below the first conductive part 121a1. Therefore, a thickness of the first pad part 121a may be greater than a thickness of the second pad part 121b by a thickness of the second conductive part 121a2. The second conductive part 121a2 of the first pad part 121a may have a width W3 smaller than the width W1 of the first conductive part 121a1. Accordingly, a side surfaced of the first pad part 121a may have a step due to a difference between the width W1 of the first conductive part 121a1 and the width W3 of the second conductive part 121a2. Through this, the embodiment can improve the bonding strength between the connection part 210 provided under the first pad part 121a and the first pad part 121a, and further, can solve an electrical short-circuit problem that may occur as the connection part 210 expands and/or spreads in the horizontal direction.

At this time, the first conductive part 121a1 and the second conductive part 121a2 of the first pad part 121a may include a same metal material, but are not limited thereto. In one example, the first conductive part 121a1 and the second conductive part 121a2 of the first pad part 121a may each include copper. In another example, any one of the first conductive part 121a1 or the second conductive part 121a2 of the first pad part 121a may include copper, and the other may include a metal material other than copper. However, in the embodiment, in order to simplify the manufacturing process while improving the electrical characteristics of the first conductive part 121a1 and the second conductive part 121a2, the first conductive part 121a1 and the second conductive part 121a2 may include a same metal material.

For example, the first pad part 121a includes a first conductive part 121a1 and a second conductive part 121a2 having different widths in the horizontal direction. This allows the side surface of the first pad part 121a to have a step, thereby increasing a contact area with the connection part 210.

For example, compared to a structure in which the first pad part 121a does not have a step, the embodiment can increase the contact area with the connection part 210 by a thickness T1 of the second conductive part 121a2 in the vertical direction, thereby improving the bonding strength with the connection part 210. Therefore, the embodiment may allow the first semiconductor device to be stably mounted, and allow the first semiconductor device to be stably operated.

In addition, the embodiment can allow the connection part 210 to be disposed under the second conductive part 121a2 of the first pad part 121a having a relatively small width, thereby reducing a volume of the connection part 210 and further inhibiting electrical short circuits from occurring due to diffusion and/or expansion of the connection part 210.

Furthermore, the embodiment can more easily control the flowability of the connection part by providing a step on the side surface of the first pad part 121a, thereby resolving electrical short circuit problems that may occur due to expansion and/or diffusion of the connection part 210 in the horizontal direction. For example, a cross-sectional area of the first pad part 121a can be increased by providing a step on the side surface of the first pad part 121a. In addition, as the cross-sectional area of the first pad part 121a increases, a distance between adjacent connection parts can be increased, thereby solving the electrical short-circuit problem in which adjacent connection parts are electrically connected to each other due to diffusion and/or expansion of the connection parts.

In addition, the thickness of the first pad part 121a in the vertical direction may be smaller than the thickness of the first protective layer 150 in the vertical direction. For example, a sum of the thickness of the first conductive part 121a1 and the thickness of the second conductive part 121a2 of the first pad part 121a may be smaller than the thickness of the first protective layer 150. For example, the lower surface of the second conductive part 121a2 of the first pad part 121a may be positioned higher than the lower surface of the first protective layer 150. Accordingly, the embodiment can facilitate the injection of the first molding member 230 into the through hole 151 of the first protective layer 150, thereby improving mold injection characteristics and product yield.

In addition, the circuit board 100 may include a bump part 140. The bump part 140 may be provided on the lower surface of the second pad part 121b of the first wiring layer 121.

The bump part 140 may be provided to surround the first pad part 121a. Referring to FIG. 5, the bump part 140 may overlap at least a portion of the first pad part 121a in the horizontal direction. For example, the bump part 140 may overlap the second conductive part 121a2 of the first pad part 121a in the horizontal direction. The bump part 140 may have a second thickness T2 greater than the thickness T1 of the second conductive part 121a2 of the first pad part 121a.

In the embodiment, the bump part 140 having a thickness greater than the second conductive part 121a2 of the first pad part 121a is disposed in the outer region R2 of the lower surface 110L of the insulating layer 110. Through this, the embodiment can further enhance the rigidity of the outer region R2 of the circuit board 100, thereby more effectively inhibiting the circuit board 100 from being significantly warped in a specific direction.

That is, the embodiment can reduce the process difficulty in the process of mounting a semiconductor device on the first pad part 121a by having the first conductive part 121a1 and the second conductive part 121a2, thereby improving the product yield. Furthermore, the embodiment can have a bump part 140 provided around the second conductive part 121a2 of the first pad part 121a, thereby securing the rigidity of the circuit board 100 and inhibiting the circuit board from being significantly warped in a specific direction.

Referring again to FIGS. 1 and 2, the circuit board 100 includes a protective layer.

For example, the circuit board includes a first protective layer 150 disposed under an insulating layer 110 and a second protective layer 160 disposed on the insulating layer 110. At this time, the first protective layer 150 may be referred to as a lower protective layer, and the second protective layer 160 may be referred to as an upper protective layer.

The first protective layer 150 and the second protective layer 160 may function to protect a component of the circuit board 100. For example, the first protective layer 150 may function to protect the lower surface 110L of the insulating layer 110 and the side surface and/or the lower surface of the first wiring layer 121. In addition, the second protective layer 160 may function to protect the upper surface of the insulating layer 110 and the side surface and/or the upper surface of the second wiring layer 122. For example, the first protective layer 150 and the second protective layer 160 can stably protect the circuit board 100 from electrical short circuits caused by contact between solders disposed on the electrode parts of the circuit board due to poor wettability with solder, and can also protect the circuit board 100 from external contaminants such as moisture or particles that may be exposed during the manufacturing process of the circuit board 100.

As illustrated in FIGS. 1, 2, and 6, the first protective layer 150 may include a through hole 151. The through hole 151 overlaps with the inner region R1 of the lower surface 110L of the insulating layer 110 in the vertical direction. For example, the through hole 151 overlaps with the first pad part 121a of the first wiring layer 121 disposed on the lower surface 110L of the insulating layer 110 in the vertical direction.

The through hole 151 of the first protective layer 150 overlaps with the plurality of first pads of the first pad part 121a in the vertical direction. For example, the first protective layer 150 may be provided with a single through hole 151, and the single through hole 151 overlaps with the plurality of first pads of the first pad part 121a in the vertical direction. This inhibits deterioration of the injection characteristics of the first molding member 230 that may occur due to the first protective layer 150 being disposed between the plurality of first pads of the first pad part 121a.

Furthermore, if the circuit board 100 is warped in a convex shape toward an upward direction, the injection characteristics of the first molding member 230 may further deteriorate. In this embodiment, the first protective layer 150 has a single through hole 151 and overlaps with a plurality of first pads of the first pad part 121a in the vertical direction through the through hole 151, thereby further improving the injection characteristics of the first molding member 230.

The first protective layer 150 may have a first opening 152 spaced apart from the through hole 151.

At this time, the through hole 151 and the first opening 152 may be identical in that they penetrate the first protective layer 150, and may be distinguished based on their area. For example, the through hole 151 has a relatively large area, and thus may overlap the first pad part 121a in the vertical direction. For example, the first opening 152 has a relatively small area, and thus, one first opening may overlap one second pad part 121b in the vertical direction.

The first protective layer 150 may have a plurality of first openings 152, and each of the plurality of first openings 152 may correspond to a second pad part 121b of the first wiring layer 121 provided on the lower surface 110L of the insulating layer 110. For example, each of the plurality of first openings 152 of the first protective layer 150 may overlap each of the plurality of second pads of the second pad part 121b in the vertical direction. For example, each of the plurality of first openings 152 of the first protective layer 150 may correspond to a bump part 140 positioned below the second pad part 121b. For example, the bump part 140 may penetrate the first protective layer 150, and thus, at least a portion of the bump part 140 may be disposed in the first opening 152 provided in the first protective layer 150.

A width of the first opening 152 of the first protective layer 150 may be smaller than the width of the second pad part 121b. Accordingly, at least a portion of the lower surface of the second pad part 121b may be covered by the first protective layer 150, and at least a remaining portion may overlap the first opening 152 in the vertical direction and come into contact with the bump part 140.

The second protective layer 160 may be disposed on the upper surface of the insulating layer 110. The second protective layer 160 may include a second opening 161. The second opening 161 of the second protective layer 160 may be provided to correspond to each pad of the second wiring layer 122 provided on the upper surface of the insulating layer 110.

A thickness of the first protective layer 150 in the vertical direction is different from a thickness of the second protective layer 160 in the vertical direction. For example, the thickness T3 of the first protective layer 150 in the vertical direction is smaller than the thickness T4 of the second protective layer 160 in the vertical direction. Through this, the embodiment can inhibit the circuit board 100 from being significantly warped in a specific direction, and further, can solve the problem of deterioration of the injection characteristics of the first molding member 230 that may occur due to the circuit board 100 being warped in a specific direction.

That is, a wiring density of the first wiring layer 121 provided on the lower surface of the insulating layer 110 may be different from a wiring density of the second wiring layer 122 provided on the upper surface of the insulating layer 110. For example, the wiring density of the first wiring layer 121 may be lower than the wiring density of the second wiring layer 122. In addition, depending on the difference in wiring density between the first wiring layer 121 and the second wiring layer 122, the circuit board 100 may be warped with a convex shape or a concave shape. For example, since the wiring density of the first wiring layer 121 is lower than the wiring density of the second wiring layer 122, the circuit board 100 may be warped with a convex shape in the upward direction.

In the embodiment, the thickness T3 of the first protective layer 150 is set to be lower than the thickness T4 of the second protective layer 160. At this time, when the thickness T3 of the first protective layer 150 and the thickness T4 of the second protective layer 160 are different from each other, the circuit board 100 may be warped in a specific direction due to a difference between the stress due to thermal expansion and/or thermal contraction acting on the first protective layer 150 and the stress due to thermal expansion and/or thermal contraction acting on the second protective layer 160. For example, when the first wiring layer 121 and the second wiring layer 122 have a same wiring density, both ends of the circuit board 100 may be warped in a direction in which the protective layer having a relatively large thickness is located. For example, if the first wiring layer 121 and the second wiring layer 122 have the same wiring density and the thickness T3 of the first protective layer 150 is smaller than the thickness T4 of the second protective layer 160, both ends of the circuit board 100 may be warped in a direction toward the second protective layer 160, and thus the circuit board 100 may be warped with a concave shape.

At this time, since the wiring density of the first wiring layer 121 is smaller than the wiring density of the second wiring layer 122, the circuit board 100 may be warped with a convex shape, and since the thickness T3 of the first protective layer 150 is smaller than the thickness T4 of the second protective layer 160, the circuit board 100 may be warped with a concave shape toward a downward direction. That is, the embodiment can induce the circuit board 100 to warp in an opposite direction to a direction in which the circuit board 100 warps due to the difference in wiring density between the first wiring layer 121 and the second wiring layer 122 by making the thickness T3 of the first protective layer 150 smaller than the thickness T4 of the second protective layer 160, thereby inhibiting the circuit board 100 from being significantly warped in a specific direction. Through this, the embodiment can enable the semiconductor device to be more stably mounted on the circuit board, and further improve the operational reliability of products such as semiconductor packages and servers including the same.

In another embodiment, when the circuit board 100 is warped with a concave shape, the thickness of the second protective layer 160 can be made greater than the thickness of the first protective layer 150. In addition, when the circuit board 100 is warped with a concave shape, the first pad part 121a may include only the first conductive part 121a1, and the third pad part of the second wiring layer 122 may include the first conductive part and the second conductive part corresponding to the first pad part 121a described above.

In addition, the embodiment can improve the molding injection characteristics in a process of injecting the first molding member 230 by making the thickness T3 of the first protective layer 150 smaller than the thickness T4 of the second protective layer 122.

For example, by making the thickness T3 of the first protective layer 150 smaller than the thickness T4 of the second protective layer 160, a vertical distance between the lower surface of the first protective layer 150 and the semiconductor device 220 can be increased compared to the comparative example, thereby improving the molding injection characteristics that increase in proportion to the vertical distance.

Referring to FIG. 7(a) and 7(b), the circuit board 100 can be warped to have a convex shape in the upward direction. At this time, when the circuit board 100 is warped with a convex shape, the vertical distance between the lower surface of the first protective layer 150 provided on the circuit board 100 and the upper surface of the semiconductor device 220 may decrease.

For example, as shown in FIG. 7(a), in the comparative example, when the circuit board 100 is warped with a convex shape, the vertical distance D1 between the lower surface of the first protective layer 150a and the upper surface of the semiconductor device 220 may decrease to 30 μm or less, 25 μm or less, or 20 μm or less. Accordingly, in the comparative example, since the vertical distance D1 between the lower surface of the first protective layer 150a and the upper surface of the semiconductor device 220 is not secured above a certain level, the mold injection characteristics in the process of injecting the first molding member 230 may deteriorate. In addition, when the mold injection characteristics are deteriorated, voids may be formed in the first molding member 230, and the semiconductor device 220 may not be stably protected by the first molding member 230.

In contrast, as shown in FIG. 7(b), in the circuit board 100 of the embodiment, a thickness T3 of the first protective layer 150 is smaller than the thickness T4 of the second protective layer 160, thereby increasing the vertical distance D2 between the lower surface of the first protective layer 150 and the upper surface of the semiconductor device 220. For example, the vertical distance D2 between the lower surface of the first protective layer 150 of the embodiment and the upper surface of the semiconductor device 220 may be greater than 35 μm, greater than 40 μm, or greater than 45 μm. For example, the embodiment may increase the vertical distance D2 by the difference between the thickness T3 of the first protective layer 150 and the thickness T4 of the second protective layer 160, thereby allowing the first molding member 230 to be smoothly injected into the through hole 151 of the first protective layer 150. Through this, the embodiment may inhibit voids from being formed in the first molding member 230, thereby ensuring the rigidity of the first molding member 230. Furthermore, the embodiment may allow the semiconductor device 220 to be stably protected by the first molding member 230, thereby allowing the semiconductor device 220 to operate more stably.

In addition, referring to FIG. 8, the through hole 151 of the first protective layer 150 of the embodiment may have an area larger than a planar area of the semiconductor device 220. For example, the first protective layer 150 may not overlap with the semiconductor device 220 in the vertical direction. For example, an inner wall of the through hole 151 of the first protective layer 150 may be provided at a predetermined distance W4 from the outer surface of the semiconductor device 220 along a circumferential direction of the outer surface of the semiconductor device 220. For example, the inner wall of the through hole 151 of the first protective layer 150 may be positioned closer to the side surface 110S of the insulating layer 110 than to the outer surface of the semiconductor device 220. For example, the inner wall of the through hole 151 of the first protective layer 150 may not overlap with the semiconductor device 220 in the vertical direction. Through this, the embodiment can further improve the mold injection characteristics of the first molding member 230, and thereby further improve the physical reliability of the first molding member 230.

Referring to FIG. 9(a), at least a portion of the first protective layer 150a of the comparative example may overlap with the semiconductor device 220 in the vertical direction. For example, the inner wall of the through hole 151 of the first protective layer 150a of the comparative example may overlap with the semiconductor device 220 in the vertical direction. Accordingly, in the comparative example, the upper surface of the semiconductor device 220 and at least a portion of the lower surface of the first protective layer 150a overlap in the vertical direction, and thus, the injection of the first molding member 230 may be performed in a space corresponding to the vertical distance D3 between the upper surface of the semiconductor device 220 and the lower surface of the first protective layer 150a.

Referring to FIG. 9(b), the first protective layer 150 of the embodiment may not overlap with the semiconductor device 220 in the vertical direction. For example, the inner wall of the through hole 151 of the first protective layer 150 may not overlap with the semiconductor device 220 in the vertical direction. For example, the inner wall of the through hole 151 of the first protective layer 150 may be provided to be spaced apart from the outer surface of the semiconductor device 220 by a predetermined distance W4 along the circumferential direction of the outer surface of the semiconductor device 220. Accordingly, in the embodiment, the first protective layer 150 and the semiconductor device 220 may not overlap in the vertical direction, and accordingly, the injection of the first molding member 230 may be performed in a space corresponding to the vertical distance D4 between the upper surface of the semiconductor device 220 and the lower surface of the insulating layer 110. For example, the embodiment may secure more space for the injection of the first molding member 230 by the thickness T3 of the first protective layer 150 compared to the comparative example. For example, the embodiment may secure a vertical distance D4 corresponding to the space for injection of the first molding member 230 to be 40 μm or more, 45 μm or more, or 50 μm or more. Through this, the embodiment may further improve the mold injection characteristics of the first molding member 230.

Referring again to FIG. 2, the semiconductor package of the embodiment includes connection parts 210 and 240.

The semiconductor package may include a first connection part 210 provided on the lower surface of a first pad part 121a of a first wiring layer 121 of a circuit board 100. For example, the first connection part 210 may be disposed on the lower surface of a second conductive part 121a2 of the first pad part 121a. The first connection part 210 may be provided to surround a side surface of the second conductive part 121a2 of the first pad part 121a.

In addition, the semiconductor package may include a second connection part 240 disposed on the upper surface of the second wiring layer 122 of the circuit board 100.

The first and second connection parts 210 and 240 may utilize at least one bonding method among wire bonding, solder bonding, and direct metal-to-metal bonding.

The wire bonding method refers to electrically connecting the electrode part (the first pad of the first wiring layer and/or the third pad part of the second wiring layer) of the circuit board 100 and the terminal of the semiconductor device using a conductive wire such as gold (Au).

The solder bonding method electrically connects the electrode part of the circuit board 100 and the terminal of the semiconductor device using a material including at least one of Sn, Ag, and Cu.

The direct metal-to-metal bonding method refers to directly bonding the electrode part and the terminal of the semiconductor device by applying heat and pressure between the electrode part and the terminal of the semiconductor device without using solder, wire, or conductive adhesive, thereby recrystallizing the electrode part. At this time, the first and second connection parts 210 and 240 may mean a metal layer between an electrode part and a terminal of a semiconductor device provided by recrystallization.

For example, the first and second connection parts 210 and 240 can electrically connect the electrode part and the terminal of the semiconductor device using a thermal compression bonding method. The thermal compression bonding method can reduce the volume of the first and second connection parts 210 and 240 and inhibit short circuits between adjacent connection parts. Therefore, the thermal compression bonding method may be advantageous when the terminals and/or electrode parts of the semiconductor device have a fine pitch.

Furthermore, the semiconductor package may include a semiconductor device disposed on the first and second connection parts 210 and 240.

For example, the semiconductor package includes a first semiconductor device 220 coupled to the first connection part 210. The first semiconductor device 220 may include a terminal 221. The terminal 221 of the first semiconductor device 220 can be electrically connected to the second conductive part 121a2 of the first pad part 121a of the circuit board 100 via the first connection part 210. According to an embodiment, the first semiconductor device 220 may include a conductive pillar 222 disposed on the terminal 221, but is not limited thereto. The conductive pillar 222 separates the terminal 221 of the first semiconductor device 220 and the first pad part 121a from each other at a predetermined distance in the vertical direction, thereby improving the alignment between the terminal 221 of the first semiconductor device 220 and the first pad part 121a.

The embodiment may include a first molding member 230. The first molding member 230 may be provided on the lower surface of the insulating layer 110. The first molding member 230 can mold the first semiconductor device 220. Furthermore, the first molding member 230 can mold the bump part 140.

A lower surface of the first molding member 230 may not be lower than the lower surface of the first semiconductor device 220. For example, the lower surface of the first molding member 230 may be coplanar with the lower surface of the first semiconductor device 220. For example, the lower surface of the first semiconductor device 220 may not be covered by the first molding member 230. Thus, the embodiment allows the first semiconductor device 220 to be exposed to an outside of the circuit board 100, thereby facilitating the dissipation of heat generated from the first semiconductor device 220. Therefore, the embodiment can improve the heat dissipation characteristics of the semiconductor package, thereby enabling the first semiconductor device 220 to operate more stably.

The semiconductor package may include a second semiconductor device 250 disposed on a second connection part 240. A plurality of second semiconductor devices 250 may be spaced apart from each other in a horizontal direction on the circuit board 100. A terminal 251 of the second semiconductor device 250 may be electrically connected to the second wiring layer 122 of the circuit board 100 via the second connection part 240.

The semiconductor package may include a second molding member 260. The second molding member 260 may mold the second semiconductor device 250.

FIG. 10 is a cross-sectional view illustrating a circuit board according to a second embodiment.

Referring to FIG. 10, the circuit board 1000 may differ from the circuit board 100 of FIG. 1 in a shape of the opening provided in the first protective layer. At this time, in the circuit board 1000 of the second embodiment, same reference numerals are assigned to components that are substantially the same as those of the circuit board 100 of the first embodiment, and a detailed description thereof is omitted.

The opening 152 of the first protective layer 150 of the circuit board 100 of the first embodiment may have a width smaller than that of the second pad part 121b, and accordingly, a side surface of the bump part 140 may be provided with a step. For example, the opening 152 of the first protective layer 150 of the first embodiment may be an SMD (Solder Mask Defined) type opening.

The first protective layer 1150 of the second embodiment includes a through hole 1151 and a first opening 1152. The through hole 1151 of the first protective layer 1150 may have a same structure as the through hole 151 of the first embodiment.

The first protective layer 1150 of the second embodiment includes an opening 1152. The opening 1152 of the first protective layer 1150 may be a Non-Solder Mask Defined (NSMD) type opening.

For example, the opening 1152 of the first protective layer 1150 may have a width greater than that of the second pad part 121b. Furthermore, a bump part 140 may be provided on the lower surface of the second pad part 121b. For example, the bump part 140 may not contact the first protective layer 1150. Furthermore, the bump part 140 may not vary in width from the upper surface to the lower surface. Through this, the embodiment can allow the width of the first opening 1152 of the first protective layer 1150 to be greater than the width of the second pad part 121b, thereby inhibiting the side surface of the bump part 140 from having a step. The embodiment allows a spacing between a plurality of bumps of the bump part 140 to be further spaced apart, thereby improving the electrical reliability of the circuit board and the semiconductor package.

FIG. 11 is a cross-sectional view illustrating a circuit board according to a third embodiment.

Referring to FIG. 11, the circuit board 2000 may differ from the circuit board 100 of FIG. 1 in that a second bump part 2100 is additionally disposed on the second wiring layer 122.

For example, the first embodiment has a structure in which a second connection part 240 penetrating the second protective layer 160 is directly provided on the second wiring layer 122, and thus a second semiconductor device 250 is mounted on the second connection part 240.

The third embodiment further includes a second bump part 2100 penetrating the second protective layer 160. At this time, the second bump part 2100 may include a plurality of bumps, and the plurality of bumps of the second bump part 2100 may have a same height.

For example, as a width of the terminal 251 of the second semiconductor device 250 coupled on the circuit board and a pitch of the terminal 221 become smaller, when the second semiconductor device 250 is mounted by a second connection part 240 such as solder, the second connection part 240 may spread in the horizontal direction, which may cause a problem in that a plurality of second connection parts 240 are connected to each other. For example, in the embodiment, thermal compression bonding may be performed to reduce the volume of the second connection part 240. At this time, if the second bump part 2100 is not provided, the second connection part 240 is disposed on the second wiring layer 122, and thus it may be difficult to reduce the volume of the second connection part 240. This may be because a height of the second wiring layer 122 on which the second connection part 240 is disposed is positioned lower than a height of the second protective layer 160, and thus the volume of the second connection part 240 increases by a difference between the height of the second wiring layer 122 and the height of the second protective layer 160.

In particular, the width and pitch of the terminals 251 of the second semiconductor device 250 are becoming smaller, and the width and pitch of the second wiring layer 122 are becoming smaller. Accordingly, a spacing between the second wiring layers 122 may be too narrow, and when the second semiconductor device 250 is mounted by applying a second connection part 240 such as solder on the second wiring layer 122, an electrical short-circuit problem may occur in which two adjacent conductive adhesives are connected to each other as the spacing between the plurality of second connection parts 240 becomes smaller. Therefore, the embodiment provides the second bump part 2100 on the second wiring layer 122, and the second connection part 240 is disposed on the second bump part 2100 to perform the mounting process of the second semiconductor device 250. Preferably, the embodiment can perform thermal compression bonding using the second bump part 2100. Accordingly, the embodiment can allow the semiconductor device to be stably mounted on a circuit board, thereby enabling the semiconductor device to operate stably.

Furthermore, in the third embodiment, the first pad part 121a of the first wiring layer 121 provided on a lower side of the circuit board includes a first conductive part 121a1 and a second conductive part 121a2 with steps, and further, a first bump part 140 having a greater thickness than the second conductive part 121a2 of the first pad part 121a is provided on the lower surface of the second pad part 121b. Accordingly, even when the second bump part 2100 is provided on the second wiring layer 122, warping of the circuit board can be inhibited, and thus, the first semiconductor device 220 and the second semiconductor device 250 can be stably mounted on the upper and lower sides of the circuit board, respectively.

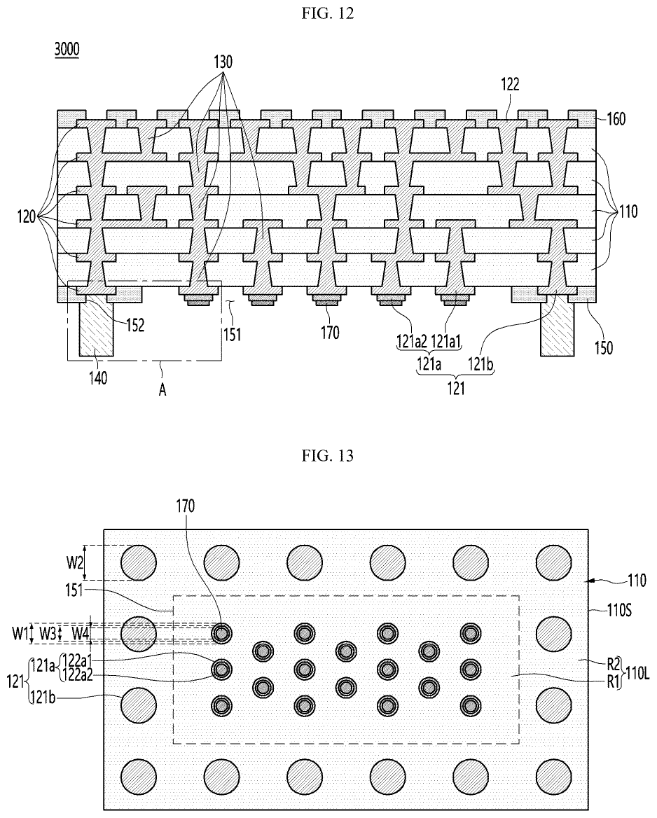

FIG. 12 is a cross-sectional view illustrating a circuit board according to a fourth embodiment.

FIG. 13 is a plan view illustrating a first wiring layer provided on the lower surface of the insulating layer of FIG. 12.

FIGS. 14 to 18 are enlarged cross-sectional views illustrating a region A of FIG. 12 according to various embodiments.

Referring to FIG. 12, the circuit board 3000 may further include a lower metal part 170 compared to the circuit board 100 of FIG. 1. The first pad part 121a may include a first conductive part 121a1 and a second conductive part 121a2, and the lower metal part 170 may overlap the first pad part 121a in a vertical direction. For example, the lower metal part 170 may be provided on the lower surface of the first pad part 121a. For example, the lower metal part 170 may be provided on the lower surface of the second conductive part 121a2 of the first pad part 121a. The lower metal part 170 may mean a configuration different from that of a solder electrically coupling the semiconductor device and the circuit board. For example, the lower metal part 170 may be a metal layer provided between the terminal of the semiconductor device and the electrode part of the circuit board. For example, the lower metal part 170 may be a surface treatment part provided on the lower surface of the first pad part 121a to improve bonding strength with the solder. For example, the lower metal part 170 may be a surface layer to inhibit the surface of the first pad part 121a from being contaminated or oxidized by moisture or various particles.

Referring to FIG. 13, the lower metal part 170 may have a different width from the width of the first pad part 121a. For example, the lower metal part 170 may have a width different from the width W3 of the second conductive part 121a2 of the first pad part 121a and may be provided under the second conductive part 121a2. FIG. 14 illustrates an inverted state of a region A of the circuit board shown in FIG. 12. Hereinafter, for convenience of description, it will be described that the first pad part 121a and the lower metal part 170 are disposed on the insulating layer 110 by rotating the circuit board of FIG. 12 by 180 degrees.

The first pad part 121a is provided on the insulating layer 110. The first pad part 121a includes the first conductive part 121a1. Additionally, the first pad part 121a includes a second conductive part 121a2 disposed on the first conductive part 121a1 and having a width smaller than that of the first lower metal part 170. Furthermore, the lower metal part 170 is disposed on the second conductive part 121a2 of the first pad part 121a.

At this time, the width of the lower metal part 170 may differ from that of the first pad part 121a. For example, the width of the lower metal part 170 may be smaller than the widths of the first conductive part 121a1 and the second conductive part 121a2 of the first pad part 121a.

Accordingly, the lower metal part 170 may be provided on the second conductive part 121a2 of the first pad part 121a with a step from the first conductive part 121a1 and the second conductive part 121a2. For example, the lower metal part 170 may be partially provided on the upper surface of the second conductive part 121a2 of the first pad part 121a. The upper surface of the second conductive part 121a2 of the first pad part 121a may include an overlapping region that overlaps with the lower metal part 170 in the vertical direction and a non-overlapping region that does not overlap with the lower metal part 170 in the vertical direction. The overlapping region of the second conductive part 121a2 of the first pad part 121a may be in contact with the lower metal part 170, and the non-overlapping region of the second conductive part 121a2 of the first pad part 121a may be in contact with the connection part 210 during the mounting process of the semiconductor device.

The lower metal part 170 includes a different metal material from the first pad part 121a. For example, the lower metal part 170 includes a different metal material from the metal materials of the first conductive part 121a1 and the second conductive part 121a2 of the first pad part 121a. For example, the lower metal part 170 may include a metal material having excellent bonding strength. For example, the lower metal part 170 may include a metal material having a high bonding strength with the connection part 210. The lower metal part 170 may include tin. For example, the lower metal part 170 may be Sn—Ag solder. In another example, the lower metal part 170 may only contain tin.

The embodiment provides a lower metal part 170 containing tin on the second conductive part 121a2 of the first pad part 121a. Through this, the embodiment can further enhance the bonding strength between the first pad part 121a and the connection part 210, and can enable a semiconductor device to be more stably mounted on the first pad part 121a.

Furthermore, the embodiment can further enhance the contact area between the connection part 210, the first pad part 121a, and the lower metal part 170 by providing a step between the lower metal part 170 and the first pad part 121a, thereby further enhancing the bonding strength. In addition, the embodiment can more easily control the flowability of the connection part 210 by providing a step between the lower metal part 170 and the first pad part 121a, thereby more effectively inhibiting electrical short-circuiting due to expansion and/or diffusion of the connection part 210.

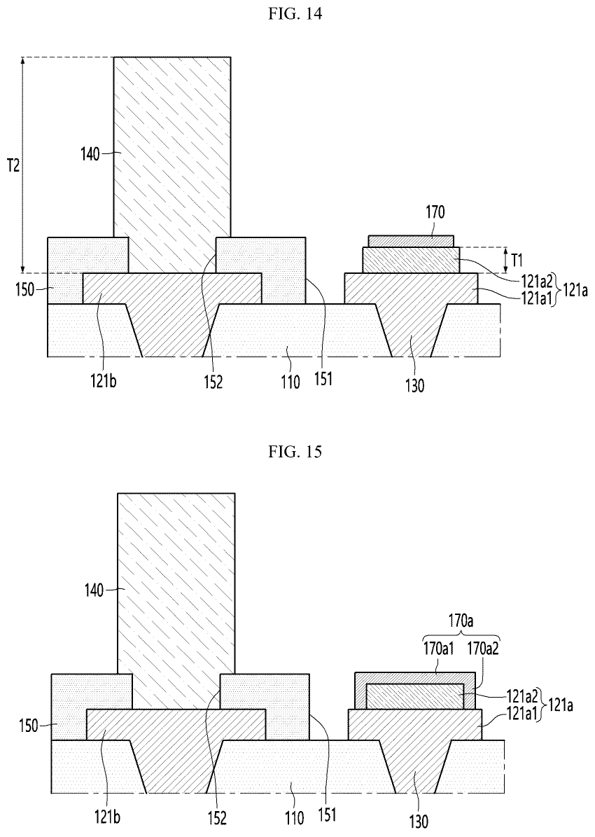

In another embodiment, the lower metal part 170a can be formed to surround at least a portion of the side surface of the first pad part 121a, as illustrated in FIG. 15. For example, the lower metal part 170 of the first embodiment is provided on the upper surface of the second conductive part 121a2 of the first pad part 121a. Alternatively, the lower metal part 170a of the second embodiment may be provided to entirely cover the upper surface of the first pad part 121a. Furthermore, the lower metal part 170a may be divided into a plurality of portions.

The lower metal part 170a may include a first portion 170a1 provided on the upper surface of the first pad part 121a. The first portion 170a1 of the lower metal part 170a may overlap the first pad part 121a in the vertical direction. For example, the first portion 170a1 of the lower metal part 170a may contact the upper surface of the second conductive part 121a2 of the first pad part 121a. Accordingly, the first portion 170a1 of the lower metal part 170a may overlap the upper surface of the second conductive part 121a2 of the first pad part 121a in the vertical direction.

The lower metal part 170a may include a second portion 170a2 extending downward from the first portion 170a1. The second portion 170a2 of the lower metal part 170a may be provided to surround a side surface of the first pad part 121a. For example, the second portion 170a2 of the lower metal part 170a may be in contact with the side surface of the first pad part 121a. Preferably, the second portion 170a2 of the lower metal part 170a may be provided to surround a side surface of the second conductive part 121a2 of the first pad part 121a. Accordingly, the embodiment allow the lower metal part 170a to include a first portion 170a1 and a second portion 170a2, thereby surrounding the upper surface and side surface of the second conductive part 121a2 of the first pad part 121a. Accordingly, the embodiment can solve reliability problems such as oxidation that may occur due to the second conductive part 121a2 of the first pad part 121a being exposed to the outside. Furthermore, the embodiment can further enhance the bonding strength between the first pad part 121a and the connection part 210 through the first portion 170a1 and the second portion 170a2 of the lower metal part 170a, thereby enabling a semiconductor device to be more stably disposed on a circuit board. At this time, an outer width of the second portion 170a2 of the lower metal part 170c (for example, a horizontal distance from an outer surface of the second portion at one side of the second conductive part 121a2 to an outer surface of the second portion at another side of the second conductive part) may be smaller than the width of the first conductive part 121a1 of the first pad part 121a. For example, at least a part of the upper surface of the first conductive part 121a1 of the first pad part 121a may overlap with the lower metal part 170a in the vertical direction, and at least a remaining part of the upper surface of the first conductive part 121a1 of the first pad part 121a may not overlap with the lower metal part 170a in the vertical direction. Accordingly, the embodiment allows the connection part 210 to flow along at least a portion of the upper surface of the first conductive part 121a1 of the first pad part 121a during diffusion and/or expansion of the connection part 210, thereby inhibiting an electrical short circuit from occurring due to the diffusion and/or expansion of the connection part 210.

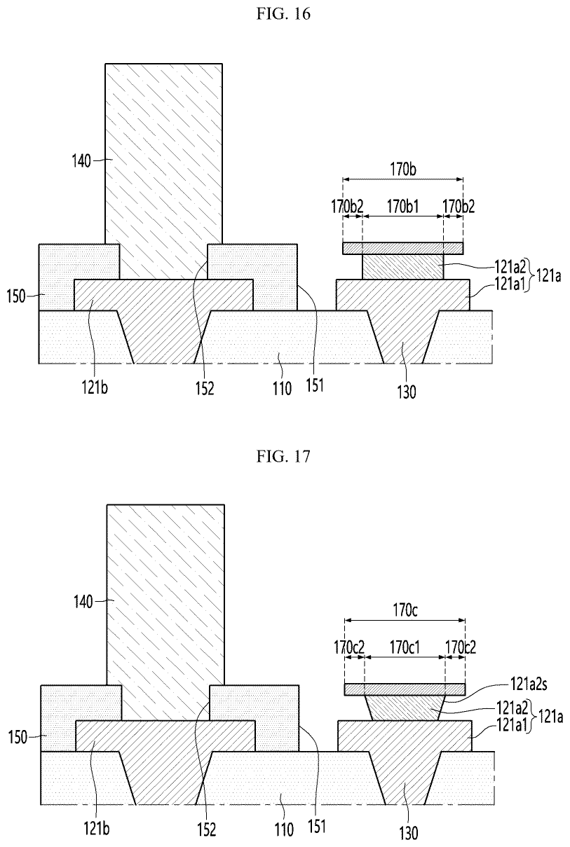

In another embodiment, the lower metal part 170b may be provided on the upper surface of the first pad part 121a, as illustrated in FIG. 16, and may have a width greater than the width of the upper surface of the first pad part 121a.

For example, the lower metal part 170b may be provided on the second conductive part 121a2 of the first pad part 121a and may have a width greater than the width of the second conductive part 121a2. In addition, the lower metal part 170b may have a width smaller than the width of the first conductive part 121a1 of the first pad part 121a.

The lower metal part 170b may include a first portion 170b1 that overlaps with an upper surface of the second conductive part 121a2 of the first pad part 121a in the vertical direction. The first portion 170b1 of the lower metal part 170b may contact an upper surface of the second conductive part 121a2 of the first pad part 121a.

The lower metal part 170b may include a second portion 170b2 that extends from the first conductive part 121a1 in a direction away from the second conductive part 121a2 of the first pad part 121a. The second portion 170b2 of the lower metal part 170b may not be in contact with the first pad part 121a. For example, the second portion 170b2 of the lower metal part 170b may not be in contact with the second conductive part 121a2 of the first pad part 121a.

In an embodiment, the lower metal part 170b may include the second portion 170b2, and the second portion 170b2 of the lower metal part 170b may be spaced apart from the first pad part 121a without being in contact with the first pad part. Accordingly, the second portion 170b2 of the lower metal part 170b may function as an anchor when coupled with the connection part 210, thereby allowing the connection part 210 to be more firmly coupled to the first pad part 121a. Accordingly, the embodiment can further improve the bonding strength between the connection part 210 and the first pad part 121a, and further enable the semiconductor device to be mounted more stably on the circuit board.

At this time, the second portion 170b2 of the lower metal part 170b may be formed by removing a portion of a side portion of the second conductive part 121a2 of the first pad part 121a during a process of removing a seed layer used to plate the first pad part 121a. For example, a width of the second portion 170b2 of the lower metal part 170b before the seed layer of the first pad part 121a is removed may be equal to or smaller than the width of the second conductive part 121a2 of the first pad part 121a. Thereafter, in the process of removing the seed layer of the first pad part 121a, a part of the side portion of the second conductive part 121a2 of the first pad part 121a may also be removed. Therefore, as the side portion of the second conductive part 121a2 of the first pad part 121 is removed, the lower metal part 170b may include a second portion 170b2 having a width greater than that of the second conductive part 121a2 of the first pad part 121a and not in contact with the second conductive part 121a2 of the first pad part 121a.

In another embodiment, the lower metal part 170c may be provided on the upper surface of the first pad part 121a, as illustrated in FIG. 17, and may have a width greater than the width of the upper surface of the first pad part 121a. In this case, FIG. 17 may differ from the structure of FIG. 16 in that the side surface of the second conductive part 121a2 of the first pad part 121a is inclined.

For example, the lower metal part 170c may be provided on the second conductive part 121a2 of the first pad part 121a and may have a width greater than the width of the second conductive part 121a2. Furthermore, the lower metal part 170c may have a width smaller than the width of the first conductive part 121a1 of the first pad part 121a.

The lower metal part 170c may include a first portion 170cl that overlaps an upper surface of a second conductive part 121a2 of the first pad part 121a in a vertical direction. The first portion 170cl of the lower metal part 170c may contact an upper surface of the second conductive part 121a2 of the first pad part 121a.

The lower metal part 170c may include a second portion 170c2 extending from the first conductive part 121a1 in a direction away from the second conductive part 121a2 of the first pad part 121a. The second portion 170c2 of the lower metal part 170c may not contact the first pad part 121a. For example, the second portion 170c2 of the lower metal part 170c may not be in contact with the second conductive part 121a2 of the first pad part 121a.

At this time, the second portion 170c2 of the lower metal part 170c may be formed by removing a portion of the side portion of the second conductive part 121a2 of the first pad part 121a during the process of removing the seed layer used to plate the first pad part 121a. For example, the width of the second portion 170b2 of the lower metal part 170b before the seed layer of the first pad part 121a is removed may be equal to or smaller than the width of the second conductive part 121a2 of the first pad part 121a. Thereafter, in the process of removing the seed layer of the first pad part 121a, a portion of the side portion of the second conductive part 121a2 of the first pad part 121a may also be removed. Accordingly, as the side portion of the second conductive part 121a2 of the first pad part 121a is removed, and the lower metal part 170c may include a second portion 170c2 having a width greater than the width of the second conductive part 121a2 of the first pad part 121a and not in contact with the second conductive part 121a2 of the first pad part 121a.

At this time, in the process of removing the seed layer of the first pad part 121a, the side portion of the second conductive part 121a2 of the first pad part 121a may be removed with different etching amounts along the thickness direction. For example, a side portion of an upper region of the second conductive part 121a2 of the first pad part 121a positioned relatively close to the lower metal part 170c may be protected by the lower metal part 170c, and thus may be removed with a relatively small etching amount in an etching process. In addition, a side portion of a lower region of the second conductive part 121a2 of the first pad part 121a positioned relatively far from the lower metal part 170c may be removed with a relatively large etching amount. Accordingly, the second conductive part 121a2 of the first pad part 121a may have an inclination 121a2s whose width decreases from the upper surface toward the lower surface. In addition, the inclination 121a2s of the second conductive part 121a2 of the first pad part 121a can further increase the contact area with the connection part 210, thereby improving the bonding strength between the connection part 210 and the first pad part 121a. Furthermore, electrical short-circuiting due to expansion and/or diffusion of the connection part 210 can be more efficiently inhibited by more smoothly controlling the flowability of the connection part 210.

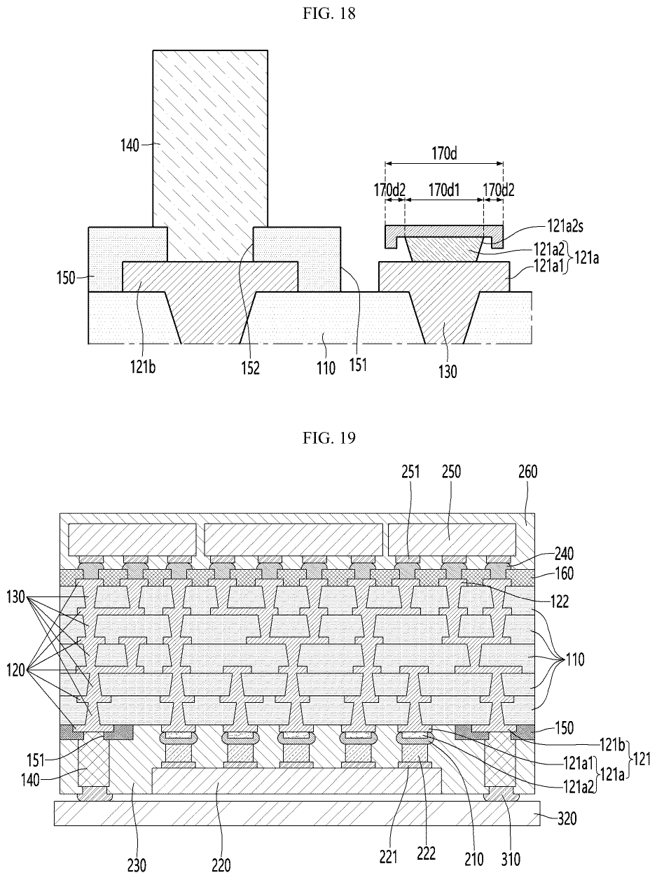

In another embodiment, the lower metal part 170d may be provided on the upper surface of the first pad part 121a, as illustrated in FIG. 18, and may have a width greater than the width of the upper surface of the first pad part 121a. In this case, FIG. 18 may differ from the structure of FIG. 17 in that the second portion of the lower metal part 170d includes a portion that is bended in a downward direction.

For example, the lower metal part 170d may be provided on the second conductive part 121a2 of the first pad part 121a and may have a width greater than the width of the second conductive part 121a2. In addition, a horizontal distance from one end of the lower metal part 170d to the other end may be smaller than the width of the first conductive part 121a1 of the first pad part 121a.

The lower metal part 170d may include a first portion 170d1 that overlaps with the upper surface of the second conductive part 121a2 of the first pad part 121a in the vertical direction. The first portion 170d1 of the lower metal part 170d may be in contact with the upper surface of the second conductive part 121a2 of the first pad part 121a.

The lower metal part 170d may include a second portion 170d2 extending from the first conductive part 121a1 in a direction away from the second conductive part 121a2 of the first pad part 121a. The second portion 170d2 of the lower metal part 170d may not contact the first pad part 121a. For example, the second portion 170d2 of the lower metal part 170d may not contact the second conductive part 121a2 of the first pad part 121a.

At this time, the second portion 170d2 of the lower metal part 170d may include a first extension portion extending from the first portion 170d2 in the horizontal direction and a second extension portion extending from an end of the first extension portion in the vertical direction. For example, the second portion 170d2 of the lower metal part 170d may further include a bend portion bended toward the insulating layer 110.

In an embodiment, the second portion 170d2 of the lower metal part 170d may further include a bend portion, which may serve as an anchor to more firmly bond the connection part 210 when coupled with the connection part 210, thereby allowing the semiconductor device to be more stably mounted on the circuit board.

FIG. 19 is a cross-sectional view illustrating a structure in which a main board is coupled to the semiconductor package of FIG. 2.

Referring to FIG. 19, the first molding member 230 of the semiconductor package may have an opening that overlaps the first bump part 140 in a vertical direction. Therefore, at least a portion of the lower surface of the first bump part 140 may not be covered by the first molding member 230. However, the embodiment is not limited thereto. For example, the lower surface of the first molding member 230 may be positioned higher than the lower surface of the first bump part 140. For example, at least a portion of the first bump part 140 may protrude below the lower surface of the first molding member 230.

A third connection part 310 may be provided on the lower surface of the first bump part 140. The third connection part 310 may be solder, but is not limited thereto.

Furthermore, the semiconductor package may include a main board 320 coupled to the first bump part 140 via the third connection part 310.

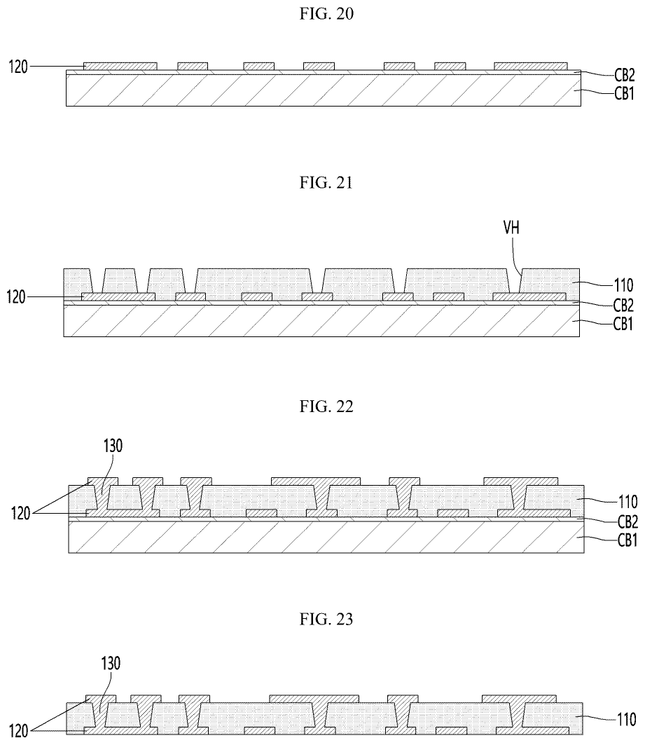

FIGS. 20 to 28 are cross-sectional views illustrating a manufacturing method of the circuit board illustrated in FIG. 1 in order of processes.

Referring to FIG. 20, the embodiment may prepare a carrier board. The carrier board may be a basic component for manufacturing a coreless substrate. The carrier board may include a carrier insulating layer CB1 and a carrier metal layer CB2 disposed on the carrier insulating layer CB1.

Next, the embodiment may proceed with a process of electroplating using the carrier metal layer CB2 as a seed layer to form a wiring electrode 120 on the carrier metal layer CB2.

Referring to FIG. 21, the embodiment may perform a process of forming an insulating layer 110 covering the wiring electrode 120 on the carrier metal layer CB2. Next, the embodiment may perform a process of forming a via hole (VH) penetrating the insulating layer 110.

Referring to FIG. 22, the embodiment may perform a process of forming a via electrode 130 by filling a via hole (VH) with a conductive material, and a process of forming a wiring electrode 120 connected to the via electrode 130 on an insulating layer 110.

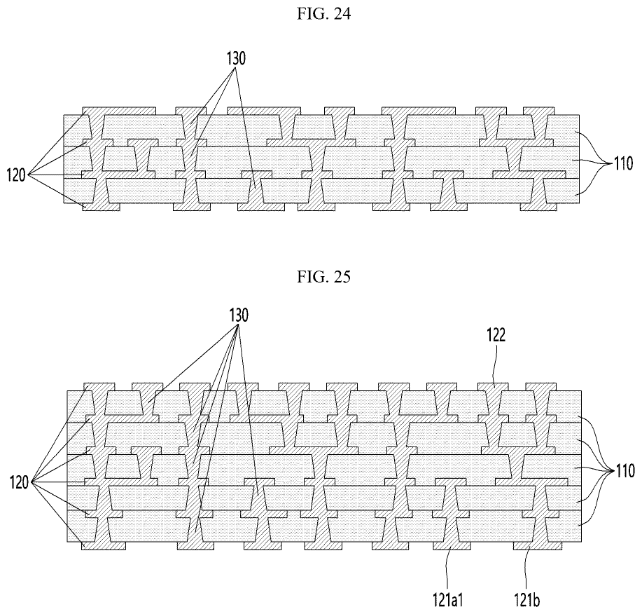

Referring to FIG. 23, the embodiment may perform a process of removing a carrier insulating layer CB1 and a carrier metal layer CB2.

Referring to FIG. 24, the embodiment may perform a process of laminating an additional build-up insulating layer 110 on upper and lower portions of the insulating layer 110 manufactured in FIG. 16, a process of forming a wiring electrode 120, and a process of forming a via electrode 130.

Referring to FIG. 25, the embodiment may perform a process of laminating an additional build-up insulating layer 110 on upper and lower portions of the insulating layer 110 manufactured in FIG. 24, a process of forming a wiring electrode 120, and a process of forming a via electrode 130. For example, the embodiment may perform a process of forming a first wiring layer 121 on an lowermost side of the circuit board 100 and a process of forming a second wiring layer 122 on an uppermost side of the circuit board 100. For example, the embodiment may form a first conductive part 121a1 and a second pad part 121b of a first pad part 121a of the first wiring layer 121.

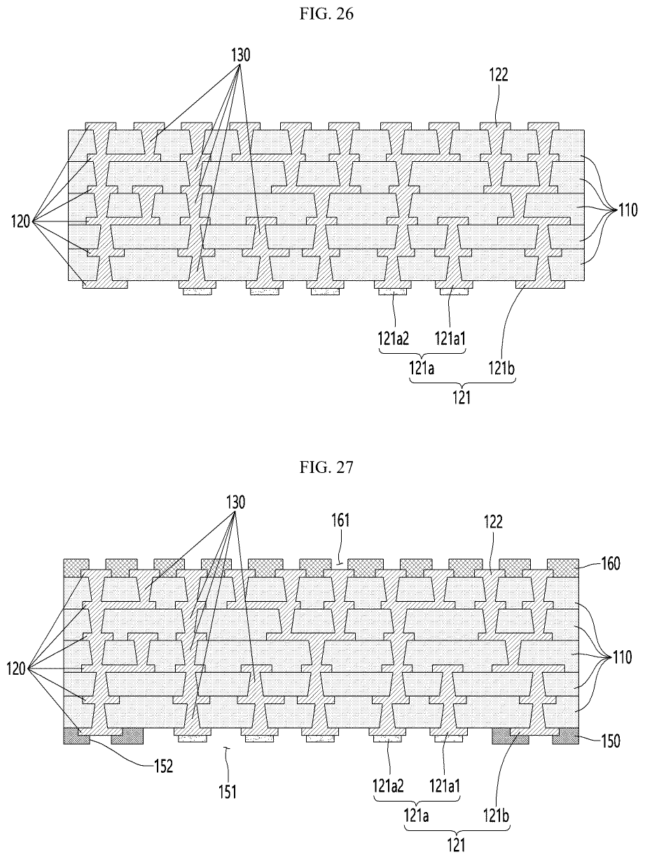

Referring to FIG. 26, the embodiment may perform a process of forming a second conductive part 121a2 under the first conductive part 121a1 of the first pad part 121a of the first wiring layer 121 in consideration of warpage direction of the circuit board. The second conductive part 121a2 of the first pad part 121a may be provided under the first conductive part 121a1 and may have a width in the horizontal direction smaller than that of the first conductive part 121a1.

Referring to FIG. 27, the embodiment may perform a process of forming a first protective layer 150 on the lower surface of the insulating layer 110 and a process of forming a second protective layer 160 on the upper surface of the insulating layer 110. At this time, the first protective layer 150 may include a through hole 151 and a first opening 152. Additionally, the second protective layer 160 may include a second opening 161.

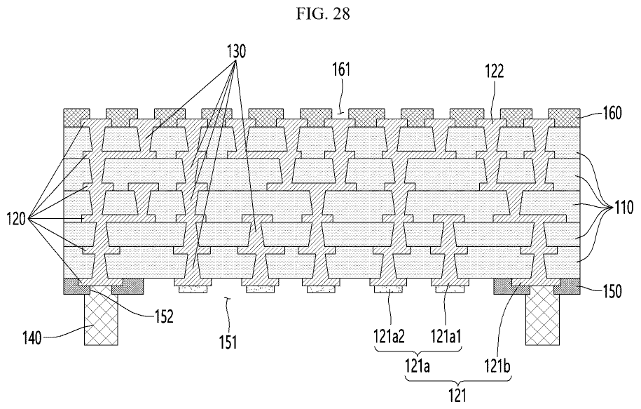

Referring to FIG. 28, the embodiment may perform a process of forming a bump part 140 on the lower surface of the second pad part 121b of the first wiring layer 121 exposed through the opening 152 of the first protective layer 150.

On the other hand, when the circuit board having the above-described characteristics of the invention is used in an IT device or home appliance such as a smart phone, a server computer, a TV, and the like, functions such as signal transmission or power supply can be stably performed. For example, when a circuit board having the features of the present invention performs a semiconductor package function, the circuit board can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
an insulating layer;
a lower pad part disposed under a lower surface of the insulating layer; and
a lower protective layer under the lower surface of the insulating layer,
wherein the lower pad part includes:
a plurality of second lower pads disposed along an edge of the lower surface of the insulating layer,
a plurality of first lower pads disposed inside the plurality of second lower pads, and
a plurality of bump parts disposed on lower surfaces of the plurality of second lower pads, and
wherein the lower protective layer includes a through hole overlapping the plurality of first lower pads in a vertical direction as a whole.

2. The circuit board of claim 1, comprising:
an upper protective layer disposed on an upper surface of the insulating layer; and
an upper pad part disposed between the upper surface of the insulating layer and the upper protective layer.

3. The circuit board of claim 2, wherein a thickness of the lower protective layer in a vertical direction is different from a thickness of the upper protective layer in the vertical direction.

4. The circuit board of claim 3, wherein the thickness of the lower protective layer in the vertical direction is smaller than the thickness of the upper protective layer in the vertical direction, and
wherein each of the plurality of first lower pads includes:
a first conductive part having a first width and disposed under the lower surface of the insulating layer; and
a second conductive part having a second width different from the first width and disposed under a lower surface of the first conductive part.

5. The circuit board of claim 4, wherein a side surface of each of the plurality of first lower pads has a step, and
wherein a side surface of at least one of the plurality of second lower pads and the upper pad part does not have a step.

6. The circuit board of claim 5, wherein a side surface of each of the plurality of second lower pads and a side surface of the plurality of upper pad part do not have steps, and
wherein a thickness of each of the plurality of first lower pads in the vertical direction is greater than a thickness of at least one of the plurality of second lower pads and the upper pad part in the vertical direction.

7. The circuit board of claim 6, wherein the thickness of each of the plurality of second lower pads and the upper pad part in the vertical direction is the same as a thickness of the first conductive part of the first lower pad in the vertical direction.

8. The circuit board of claim 4, wherein a wiring density of the lower pad part on the lower surface of the insulating layer is smaller than a wiring density of the upper pad part on the upper surface of the insulating layer.

9. The circuit board of claim 4, wherein a first width of the first conductive part is greater than a second width of the second conductive part.

10. The circuit board of claim 4, wherein at least a portion of the bump part overlaps the first conductive part of the first lower pad in a horizontal direction.

11. The circuit board of claim 2, wherein a width of the through hole of the lower protective layer is greater than a horizontal distance between two outer lower pads disposed at an outermost side among the plurality of first lower pads.

12. The circuit board of claim 11, comprising:
a first connection part disposed under the first lower pad; and
a first semiconductor device disposed under the first connection part,
wherein the through hole overlaps the first semiconductor device in the vertical direction.

13. The circuit board of claim 12, wherein a planar area of the through hole is greater than a planar area of the first semiconductor device.

14. The circuit board of claim 12, wherein an outer surface of the first semiconductor device overlaps the through hole in the vertical direction, and
wherein an inner wall of the through hole is provided with a spacing of a specific horizontal distance along a circumferential direction of the outer surface of the first semiconductor device.

15. The circuit board of claim 12, wherein a thickness of the bump part in the vertical direction is greater than a thickness of the second conductive part of the first lower pad in the vertical direction, and
wherein a lower surface of the bump part is positioned lower than a lower surface of the lower protective layer and a lower surface of the first lower pad.

16. The circuit board of claim 15, comprising:
a first molding member for molding the first semiconductor device and the bump part.

17. The circuit board of claim 12, wherein a width of the upper pad part in a horizontal direction is smaller than a width of each of the first lower pad and the second lower pad in the horizontal direction.

18. The circuit board of claim 17, comprising:
a second connection part disposed on the upper pad part;
a second semiconductor device disposed on the second connection part; and
a second molding member for molding the second semiconductor device.

19. A semiconductor package comprising:
a circuit board;
a first semiconductor device disposed under the circuit board;
a second semiconductor device disposed on the circuit board; and
a main board disposed under the first semiconductor device,
wherein the circuit board comprises:
an insulating layer;
a lower pad part including a plurality of first lower pads disposed on a lower surface of the insulating layer and overlapping the first semiconductor device in a vertical direction, and a plurality of second lower pads disposed in an outer edge region of the lower surface of the insulating layer and surrounding the plurality of first lower pads; and
a bump part disposed under the plurality of second lower pads of the lower pad part and overlapping the first semiconductor device in a horizontal direction, and
wherein the bump part is provided with a certain thickness under the circuit board and surrounding an outer surface of the first semiconductor device.

20. The semiconductor package of claim 19, wherein the circuit board comprises:
a lower protective layer disposed under the lower surface of the insulating layer;
an upper protective layer disposed on an upper surface of the insulating layer; and
an upper pad part disposed between the upper surface of the insulating layer and the upper protective layer,
wherein a thickness of the lower protective layer in the vertical direction is smaller than a thickness of the upper protective layer in the vertical direction,
wherein a thickness of the first lower pad in the vertical direction is larger than a thickness of each of the second lower pad and the upper pad part, and
wherein a width of the upper pad in the horizontal direction is smaller than a width of each of the first lower pad and the second lower pad in the horizontal direction.
